(19) United States
(12) Patent Application Publication
(10) Pub. No.: US 2026/0047275 A1
(43) Pub. Date: Feb. 12, 2026

(54) DISPLAY PANEL AND DISPLAY APPARATUS

(71) Applicant: BOE Technology Group Co., Ltd., Beijing (CN)

(72) Inventors: Hao ZHANG, Beijing (CN); Mingche HSIEH, Beijing (CN); Libin LIU, Beijing (CN)

(21) Appl. No.: 18/995,645

(22) PCT Filed: Mar. 13, 2024
(86) PCT No.: PCT/CN2024/081484

§ 371 Date: Jan. 16, 2025

(30) Foreign Application Priority Data
Apr. 26, 2023 (CN) 202310465152.8

(51) Int. Cl. H10K 59/121; H10K 59/35; H10K 59/80

(52) U.S. Cl. CPC H10K 59/1213; H10K 59/353; H10K 59/873; H10K 59/878; H10K 59/8792

(57) ABSTRACT

A display panel and a display apparatus. The display apparatus includes: a base substrate; a display structure layer, which is located on one side of the base substrate and includes sub-pixels, where one of the sub-pixels includes a pixel circuit and a light-emitting element, which is electrically connected to the pixel circuit and includes a first light-emitting unit and a second light-emitting unit; and optical components, which are located on a light emergent side of the display structure layer, where the orthographic projection of the optical component on the base substrate at least partially covers an area between the first light-emitting unit and the second light-emitting unit, and the optical component includes a shielding layer and a light reflection structure, which is located on the side of the shielding layer that faces the display structure layer.

### CROSS-REFERENCE TO RELATED APPLICATIONS

The application is a national phase entry under 35 U.S.C. §371 of International Application No. PCT/CN2024/081484, filed on Mar. 13, 2024, which claims the priority of the Chinese patent application No. 202310465152.8, filed with the China National Intellectual Property Administration on Apr. 26, 2023 and named “DISPLAY PANEL AND DISPLAY APPARATUS”, the entire content of which is incorporated herein by reference.

### TECHNICAL FIELD

The present disclosure relates to the field of the semiconductor technology, and in particular to a display panel and a display apparatus.

### BACKGROUND

With the continuous development of the display technology, people's demands for display modes are becoming increasingly diverse. In the use of some display applications, users like to share information with others. In the usage scenarios of other applications, users need to protect their privacy and require display products to have anti-peeping functions. For example, when users are inputting personal data on their mobile phones or handling confidential company information. Therefore, display sharing and privacy switching have gradually become the functional trends of display products. In the usage scenarios of some other applications, it is necessary for display products to display towards one side, while in the usage scenarios of other applications, it is necessary for display products to display towards the other side, to achieve two-way display. The two-way display mode allows different users to view respectively. For example, during a first period, only the user in the driver's seat can view, as shown in FIG. 1A; and during a second period, only the user in the front passenger's seat can view, as shown in FIG. 1B.

### SUMMARY

The present disclosure provide a display panel, including: a substrate; a display structure layer, disposed on a side of the substrate, and including a plurality of sub-pixels; where at least one of the plurality of sub-pixels includes: a pixel circuit and a light-emitting element electrically connected to the pixel circuit; the light-emitting element includes a first light-emitting unit and a second light-emitting unit; a light-emitting region of the first light-emitting unit and a light-emitting region of the second light-emitting unit are isolated from each other; and the pixel circuit is configured to drive at least one of the first light-emitting unit and the second light-emitting unit to emit light according to a display mode; and optical components disposed on a light-emitting side of the display structure layer; where an orthographic projection of the optical component on the substrate at least partially covers a region between the first light-emitting unit and the second light-emitting unit; and the optical component includes a shielding layer and a light reflection structure disposed on a side of the shielding layer facing the display structure layer.

In one possible implementation, the first light-emitting unit and the second light-emitting unit of one same light-emitting element are arranged along a first direction and extend along a second direction; and the optical component extends along the second direction.

In one possible implementation, the display structure layer includes a plurality of light-emitting element columns extending along the second direction and arranged along the first direction; in one same light-emitting element column, the first light-emitting units extend in one same direction, the second light-emitting units extend in one same direction, and the optical component between the first light-emitting unit and the second light-emitting unit which are adjacent is an integrally connected structure.

In one possible implementation, the plurality of light-emitting element columns include first light-emitting element columns and second light-emitting element columns alternately arranged along the first direction; the first light-emitting element column includes a first sub-light-emitting element which emits light of a first color and a second sub-light-emitting element which emits light of a second color; the second light-emitting element column includes a third sub-light-emitting element which emits light of a third color.

In one possible implementation, the light-emitting region of the first light-emitting unit is strip-shaped and extends along the second direction; and the light-emitting region of the second light-emitting unit is strip-shaped and extends along the second direction.

In one possible implementation, in the one same light-emitting element, an area of the light-emitting region of the first light-emitting unit is approximately equal to an area of the light-emitting region of the second light-emitting unit.

In one possible implementation, the display mode includes a first display mode and a second display mode; the pixel circuit is configured to drive only the first light-emitting unit to emit light in the first display mode and drive only the second light-emitting unit to emit light in the second display mode.

In one possible implementation, the orthographic projection of the optical component on the substrate surrounds an orthographic projection of the first light-emitting unit on the substrate.

In one possible implementation, the display structure layer includes first light-emitting element columns and second light-emitting element columns extending along a second direction and arranged along a first direction; the first light-emitting element column includes: a first sub-light-emitting element which emits light of a first color and a second sub-light-emitting element which emits light of a second color; the second light-emitting element column includes: a third sub-light-emitting element which emits light of a third color; for one same light-emitting element, the first light-emitting unit and the second light-emitting unit extend along the first direction and are arranged along the second direction; in the first sub-light-emitting element and the second sub-light-emitting element which are adjacent in the first light-emitting element column; and the optical component surrounds the second light-emitting unit and the first light-emitting unit which are adjacent in different light-emitting elements.

In one possible implementation, in the first light-emitting element column, the optical component surrounds the second light-emitting unit of the first sub-light-emitting element and the first light-emitting unit of the second sub-light-emitting element.

In one possible implementation, in the second light-emitting element column, the optical component surrounds the first light-emitting unit of the third sub-light-emitting element.

In one possible implementation, the display panel has a first symmetry line, and the first symmetry line passes through the first light-emitting unit of the third sub-light-emitting element. The first symmetry line passes through a midpoint of a line connecting a first center and a second center, the first center is a center of the second light-emitting unit of the first sub-light-emitting element, and the second center is a center of the first light-emitting unit of the second sub-light-emitting element.

In one possible implementation, the display mode includes a first display mode and a third display mode; the pixel circuit is configured to drive only the first light-emitting unit to emit light in the first display mode and drive the second light-emitting unit to emit light together with the first light-emitting unit in the third display mode.

In one possible implementation, the orthographic projection of the optical component on the substrate further covers an orthographic projection of a side region of the first light-emitting unit facing the second light-emitting unit on the substrate, and further covers an orthographic projection of a side region of the second light-emitting unit facing the first light-emitting unit on the substrate.

In one possible implementation, an orthographic projection of the shielding layer on the substrate coincides with an orthographic projection of the light reflection structure on the substrate.

In one possible implementation, the orthographic projection of the shielding layer on the substrate covers the orthographic projection of the light reflection structure on the substrate, and an area of the orthographic projection of the shielding layer on the substrate is larger than an area of the orthographic projection of the light reflection structure on the substrate.

In one possible implementation, the display panel further includes an encapsulation structure layer disposed on the light-emitting side of the display structure layer, and a first protective layer disposed on a side of the encapsulation structure layer facing away from the display structure layer. The optical components are disposed between the encapsulation structure layer and the first protective layer, and/or the optical components are disposed on a side of the first protective layer facing away from the encapsulation structure layer.

In one possible implementation, the light reflection structure includes a pit and a reflective filler filled in the pit; and the pit is disposed in the encapsulation structure layer and/or the first protective layer.

In one possible implementation, a cross-sectional shape of the pit in a direction perpendicular to the substrate is triangular, semi-circular or semi-elliptical.

Embodiments of the present disclosure further provide a display apparatus, including the display panel according to the embodiments of the present disclosure.

### BRIEF DESCRIPTION OF FIGURES

FIG. 1A is a schematic diagram when one side is displayed in the two-way display.

FIG. 1B is a schematic diagram when the other side is displayed in the two-way display.

FIG. 1C is a structural schematic diagram of a display panel according to at least one embodiment of the present disclosure.

FIG. 2 is a schematic diagram of a planar structure of a display panel according to at least one embodiment of the present disclosure.

FIG. 3A is a planar schematic diagram of sub-pixels of a display panel according to at least one embodiment of the present disclosure.

FIG. 3B is a planar schematic diagram of sub-pixels of a display panel according to at least one embodiment of the present disclosure.

FIG. 3C is a planar schematic diagram of sub-pixels of a display panel according to at least one embodiment of the present disclosure.

FIG. 4 is a schematic diagram of a pixel circuit according to at least one embodiment of the present disclosure.

FIG. 5 is an equivalent circuit diagram of a pixel circuit according to at least one embodiment of the present disclosure.

FIG. 6 is another equivalent circuit diagram of a pixel circuit according to at least one embodiment of the present disclosure.

FIG. 7 is a partial cross-sectional diagram along the Q-Q′ direction in FIG. 3B.

FIG. 8 is a planar schematic diagram of a first shielding layer according to at least one embodiment of the present disclosure.

FIG. 9 is another partial cross-sectional diagram along the Q-Q′ direction in FIG. 3B.

FIG. 10 is a schematic diagram of light emission of a cross-sectional structure along the R-R′ direction in FIG. 3B.

FIG. 11 is a schematic diagram of light emission of a cross-sectional structure along the U-U′ direction in FIG. 3B.

FIG. 12 is a schematic diagram of a display apparatus according to embodiments of the present disclosure.

### DETAILED DESCRIPTION

The following will describe embodiments of the present disclosure in detail with reference to accompanying drawings. The implementation manners can be implemented in multiple different forms. Those of ordinary skill in the art can easily understand a fact that manners and contents can be transformed into one or more forms without departing from the purpose and scope of the present disclosure. Therefore, the present disclosure should not be construed as being limited only to contents described in the following implementation manners. In the case of no conflict, embodiments in the present disclosure and features in the embodiments can be arbitrarily combined with each other.

In accompanying drawings, sometimes, for the sake of clarity, a size of one or more components, and a thickness of a layer or a region may be exaggerated. Therefore, one manner of the present disclosure is not necessarily limited to such dimensions, and shapes and sizes of components in accompanying drawings do not reflect true proportions. In addition, accompanying drawings schematically show ideal examples, and one manner of the present disclosure is not limited to shapes or values shown in the drawings.

The ordinal numbers such as “first”, “second”, “third” in the description are set to avoid confusion of components, rather than to limit the quantity. The term “plurality” in the present disclosure may include two or more quantities.

In the description, for convenience, words and phrases indicating directions or positional relationships such as “middle”, “upper”, “lower”, “front”, “rear”, “vertical”, “horizontal”, “top”, “bottom”, “inner”, “outer” are used to describe positional relationships of components with reference to accompanying drawings. This is only for the convenience of describing the description and simplifying the description, rather than indicating or implying that the referred device or element must have a specific orientation and must be constructed and operated in a specific orientation. Therefore, it should not be construed as a limitation to the present disclosure. The positional relationships of components can be appropriately changed according to a direction in which the components are described. Therefore, it is not limited to words and phrases described in the description, and they can be appropriately replaced according to the situation.

In this description, unless otherwise clearly defined and limited, terms “install”, “connect”, “couple” should be understood in a broad sense. For example, it can be a fixed connection, or a detachable connection, or an integral connection; it can be a mechanical connection or an electrical connection; and it can be a direct connection, or an indirect connection through an intermediate member, or the internal communication of two elements. For those of ordinary skill in the art, they can understand meanings of the above terms in the present disclosure according to the situation.

In the description, “electrical connection” includes a situation where components are connected together through an element having a certain electrical function. There is no particular limitation on the “element having a certain electrical function” as long as electrical signals between the connected components can be transmitted. Examples of the “element having a certain electrical function” not only include electrodes and wirings, but also include switching elements such as transistors, resistors, inductors, capacitors, and other elements having one or more functions.

In the description, a transistor refers to an element including at least three terminals: a gate electrode (gate), a drain electrode, and a source electrode. The transistor has a channel region between the drain electrode (drain electrode terminal, drain region, or drain) and the source electrode (source electrode terminal, source region, or source), and current can flow through the drain electrode, the channel region, and the source electrode. In the present disclosure, the channel region refers to a region where current mainly flows.

In the description, to distinguish two electrodes of the transistor other than the gate electrode, one electrode is called a first electrode, and the other electrode is called a second electrode. The first electrode can be the source or the drain, and the second electrode can be the drain or the source. In addition, the gate of the transistor can be called a control electrode. In a case of using transistors with opposite polarities or when a current direction changes during circuit operation, functions of the “source electrode” and the “drain electrode” may be interchanged sometimes. Therefore, in the description, the “source electrode” and the “drain electrode” can be interchanged.

In the description, “parallel” refers to a state where an angle formed by two straight lines is between −10° and 10°, and thus may include a state where the angle is between −5° and 5°. In addition, “perpendicular” refers to a state where an angle formed by two straight lines is between 80° and 100°, and thus may include a state where the angle is between 85° and 95°.

In the description, triangles, rectangles, trapezoids, pentagons, or hexagons, etc., are not in a strict sense, and may be approximate triangles, rectangles, trapezoids, pentagons, or hexagons, etc. There may be some small deformations due to tolerances, and there may be chamfers, arc edges, and deformations, etc.

In the description, “film” and “layer” can be interchanged. For example, sometimes the “conductive layer” can be replaced with “conductive film”. Similarly, sometimes the “insulating film” can be replaced with the “insulating layer”.

The terms “about” and “approximately” in the description mean that a boundary is not strictly limited, and a situation within the range of process and measurement errors is allowed. In the description, “substantially the same” may refer to a situation where values differ by less than 10%.

In the anti-peeping display, to reduce a viewing angle of an anti-peeping mode, a pixel anode loses a light-emitting area due to the division of an anti-peeping device and a shared device. When brightness is constant, the current increases, which affects the lifespan. In the vehicle-mounted anti-peeping two-way display, the light-emitting device is also divided into two, that is, left and right light-emitting devices, and the light-emitting area is reduced. The above problem also exists. In the pixel time-sharing display, the light-emitting time is halved.

When the brightness is constant, the current also needs to be increased, which affects the lifespan.

The embodiments provide a display panel, including:
a substrate;
a display structure layer, located on a side of the substrate, and including a plurality of sub-pixels; where at least one of the plurality of sub-pixels includes: a pixel circuit and a light-emitting element electrically connected to the pixel circuit; the light-emitting element includes: a first light-emitting unit and a second light-emitting unit; a light-emitting region of the first light-emitting unit and a light-emitting region of the second light-emitting unit are isolated from each other; and the pixel circuit is configured to drive at least one of the first light-emitting unit and the second light-emitting unit to emit light according to a display mode; and
an optical component located on a light-emitting side of the display structure layer; where an orthographic projection of the optical component on the substrate at least covers a region between the first light-emitting unit and the second light-emitting unit; the optical component includes: a shielding layer, and a light reflection structure located on a side of the shielding layer facing the display structure layer; and the light reflection structure is configured to reflect incident light. Specifically, the light reflection structure can be configured to reflect the light emitted by the light-emitting element and incident on the light reflection structure, and specifically, it can be reflected to a reflective anode of the light-emitting element again, and then emitted after being reflected by the reflective anode.

In the display panel provided by the embodiments of the present disclosure, the light-emitting element of the sub-pixel is divided into two light-emitting units (i.e., the first light-emitting unit and the second light-emitting unit), and different display modes are realized by controlling the light emission of the first light-emitting unit and the second light-emitting unit through the pixel circuit. Moreover, an optical component is disposed on the light-emitting side of the display structure layer. The optical component includes a shielding layer and a light reflection structure. The light reflection structure can reflect the light blocked by the shielding layer back to the light-emitting element, and then the light is reflected and emitted again by the light-emitting element. The light direction is changed, and the light output efficiency is increased, thereby improving the problem that when the light-emitting element is divided into the first light-emitting unit and the second light-emitting unit, the light-emitting area is reduced, and the current needs to be increased when the required brightness is constant, which affects the lifespan of the display panel.

In some exemplary embodiments, the display panel may include at least one optical component located on the light-emitting side of the display structure layer. The orthographic projection of the optical component on the substrate may not overlap with orthographic projections of light-emitting regions of the first light-emitting unit and the second light-emitting unit of the light-emitting element on the substrate. The orthographic projection of the optical component on the substrate may surround an orthographic projection of the first light-emitting unit of the light-emitting element on the substrate, or the orthographic projection of the optical component on the substrate may surround an orthographic projection of the light-emitting element on the substrate. In some examples, the number of optical components may be two, and a protective layer may be disposed between adjacent optical components. In the example, by arranging at least one optical component around the light-emitting element or the first light-emitting unit of the light-emitting element, a light emission angle of the first light-emitting unit of the light-emitting element can be limited, which is conducive to realizing the effect of anti-peeping or two-way display.

In some exemplary embodiments, the display panel may be an organic light-emitting diode (OLED) display panel, or quantum dot light-emitting diodes (QLED) display panel, or a plasma display panel (PDP), or an electrophoretic display (EPD) panel. The embodiments are not limited thereto.

In some exemplary embodiments, the display panel may include an anti-peeping display mode and a sharing display mode. The anti-peeping display mode can meet a display requirement of users who need to protect their privacy, and the sharing display mode can meet a display requirement of users in the information sharing scenario. In some exemplary embodiments, the vehicle-mounted display panel may include a two-way display mode and a sharing display mode. The two-way display mode allows different users to view respectively.

For example, in a first period, only the user in the driver's seat can view, and in a second period, only the user in the front passenger's seat can view. In some examples, the display panel may be provided with a switching key, and the user can switch a display mode of the display panel by the switching key. However, this embodiment is not limited thereto. In other examples, voice control, induction and other triggering methods can be used to switch the display mode of the display panel.

In some exemplary embodiments, the display mode may include a first display mode and a second display mode; or, the display mode may also include: a first display mode and a third display mode. The pixel circuit can be configured to drive only the first light-emitting unit to emit light in the first display mode (such as the anti-peeping display mode or a left display mode in the two-way display mode), drive only the second light-emitting unit to emit light in the second display mode (such as a right display mode in the two-way display mode), and drive the second light-emitting unit to emit light together with the first light-emitting unit in the third display mode (such as the sharing display mode). In other examples, the pixel circuit can be configured to drive only the second light-emitting unit to emit light or drive the first light-emitting unit and the second light-emitting unit to emit light respectively in the first display mode (such as the anti-peeping display mode or a left display mode in the two-way display mode), drive only the first light-emitting unit to emit light in the second display mode (such as a right display mode in the two-way display mode), and drive the second light-emitting unit to emit light together with the first light-emitting unit in the third display mode (such as the sharing display mode). However, this embodiment is not limited thereto.

The following illustrates solutions of the embodiments through some examples.

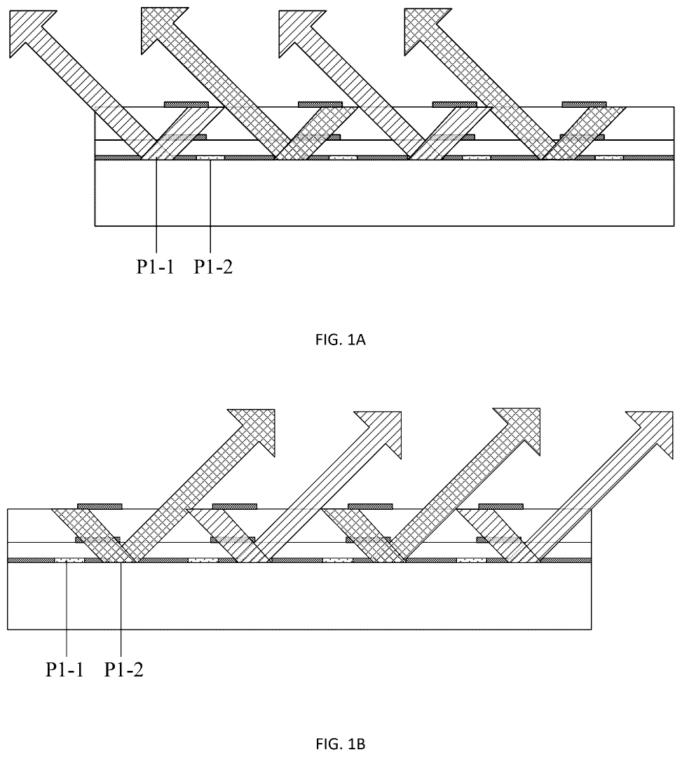

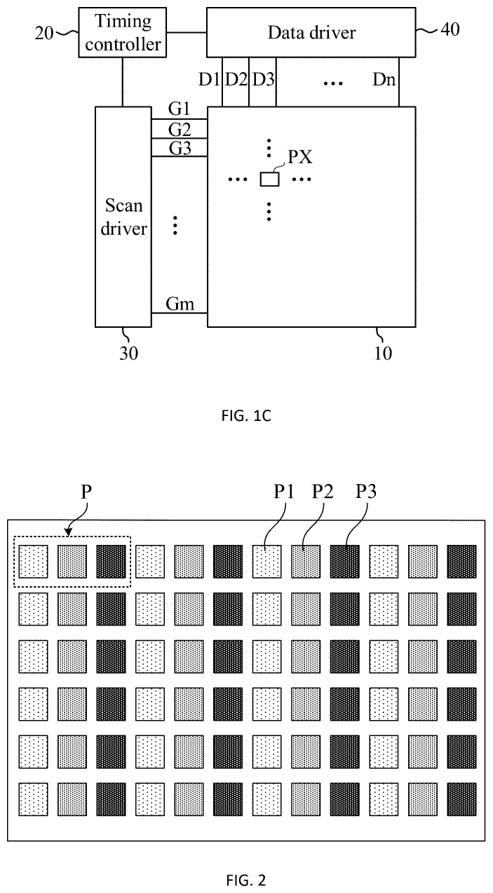

FIG. 1C is a schematic structural diagram of the display panel according to at least one embodiment of the present disclosure. In some examples, as shown in FIG. 1C, the display panel may include: a timing controller 20, a data driver 40, a gate driving circuit, and a sub-pixel array 10. The gate driving circuit may include at least one driver, for example, including a scan driver 30. The timing controller 20, the data driver 40, and the gate driving circuit may be located in a peripheral region around a display region of the display panel. The sub-pixel array 10 located in the display region may include a plurality of sub-pixels PX arranged regularly. The scan driver 30 can be configured to provide scan signals to the sub-pixels PX along scan lines; the data driver 40 can be configured to provide data signals to the sub-pixels PX along data lines; and the timing controller 20 can be configured to control the scan driver 30 and the data driver 40.

In some examples, the timing controller 20 can provide a gray value and a control signal suitable for the specification of the data driver 40 to the data driver 40; the timing controller 20 can provide a clock signal, an initial signal, etc., suitable for the specification of the scan driver 30 to the scan driver 30. The data driver 40 can use the gray value and the control signal from the timing controller 20 to generate the data voltage to be provided to data lines D1 to Dn. For example, the data driver 40 can sample the gray value by using the clock signal, and apply a data signal corresponding to the gray value to data lines D1 to Dn in a unit of a sub-pixel row.

The scan driver 30 can generate a scan signal to be provided to scan lines G1 to Gm by using the clock signal, initial signal, etc., from the timing controller 20. For example, the scan driver 30 can sequentially provide the scan signal with a conducting level pulse to the scan lines. In some examples, the scan driver 30 may include a shift register, and can generate the scan signal by sequentially transmitting the scan initial signal provided in the form of a conducting level pulse to the next stage circuit under the control of the clock signal. Here, both n and m are natural numbers.

In some examples, the gate driving circuit may be directly arranged on the substrate. For example, the gate driver may be arranged in the peripheral region on left and right sides of the display region. In some examples, the gate driver may be formed together with the sub-pixels in a process of forming the sub-pixels. However, this embodiment does not limit the position or formation method of the gate driver. In some examples, the gate driver may be arranged on a separate chip or a printed circuit board to be connected to a pad or a solder pad formed on the substrate.

In some examples, the data driver 40 may be arranged on a separate chip or a printed circuit board to be connected to the sub-pixels PX through signal access pins arranged on the substrate. For example, the data driver 40 may be formed and arranged by using chip on glass, chip on plastic, chip on film, etc., to be connected to the signal access pins on the substrate. The timing controller 20 may be separately arranged from the data driver 40 or integrally arranged with the data driver 40. However, this embodiment is not limited thereto.

FIG. 2 is a schematic diagram of a planar structure of the display panel according to at least one embodiment of the present disclosure. In some examples, as shown in FIG. 2, the display region of the display panel may include a plurality of pixel units P arranged in a matrix manner. At least one of the plurality of pixel units P may include a first sub-pixel P1 that emits light of a first color, a second sub-pixel P2 that emits light of a second color, and a third sub-pixel P3 that emits light of a third color. For example, the light of a first color may be red light, the light of a second color may be green light, and the light of a third color may be blue light. In other words, the first sub-pixel P1 may be a red (R) sub-pixel, the second sub-pixel P2 may be a green (G) sub-pixel, and the third sub-pixel P3 may be a blue (B) sub-pixel. In other examples, the pixel unit P may include four sub-pixels, such as a red sub-pixel, a green sub-pixel, a blue sub-pixel, and a white sub-pixel. However, the present disclosure is not limited thereto.

In some examples, a shape of the sub-pixels in the pixel unit P may be rectangular, diamond-shaped, pentagonal, or hexagonal. As shown in FIG. 2, the shape of the sub-pixels in the pixel unit P may be rectangular. For example, when the pixel unit P includes three sub-pixels, three sub-pixels may be arranged horizontally side by side, vertically side by side, or in a triangular pattern; and when the pixel unit includes four sub-pixels, four sub-pixels may be arranged horizontally side by side, vertically side by side, or in a square pattern. However, the present disclosure is not limited thereto.

In some examples, at least one sub-pixel may include a pixel circuit and a light-emitting element. For example, the first sub-pixel P1, the second sub-pixel P2, and the third sub-pixel P3 may all include a pixel circuit and a light-emitting element. In some examples, the pixel circuit may include a plurality of transistors and at least one capacitor. For example, the pixel circuit may have a 3T1C structure, a 7T1C structure, a 5T1C structure, an 8T1C structure, or an 8T2C structure, etc. Here, in the above circuit structures, T refers to a thin film transistor, C refers to a capacitor, the number before T represents the quantity of thin film transistors in the circuit, and the number before C represents the quantity of capacitors in the circuit.

In some examples, light-emitting elements in the first sub-pixel P1, the second sub-pixel P2 and the third sub-pixel P3 are respectively connected to pixel circuits of the corresponding sub-pixels, and the light-emitting elements can be configured to emit light with corresponding brightness in response to a driving current output by the pixel circuits of the corresponding sub-pixels. For example, the light-emitting element may be an organic light-emitting diode (OLED), which may include a first electrode (anode), an organic light-emitting layer, and a second electrode (cathode) stacked. However, this embodiment is not limited thereto. For example, the light-emitting element may be a micro light-emitting diode (Micro-LED), or a mini light-emitting diode (Mini-LED), or a quantum dot light-emitting diode (QLED).

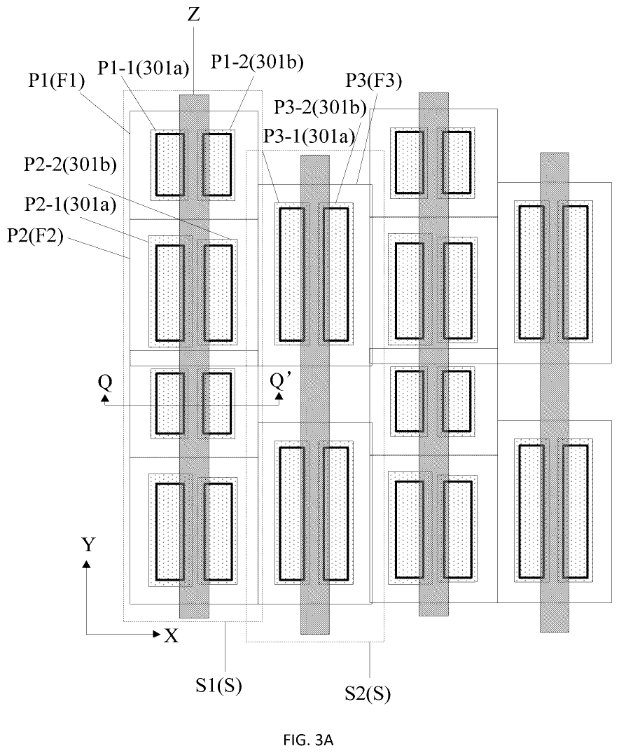

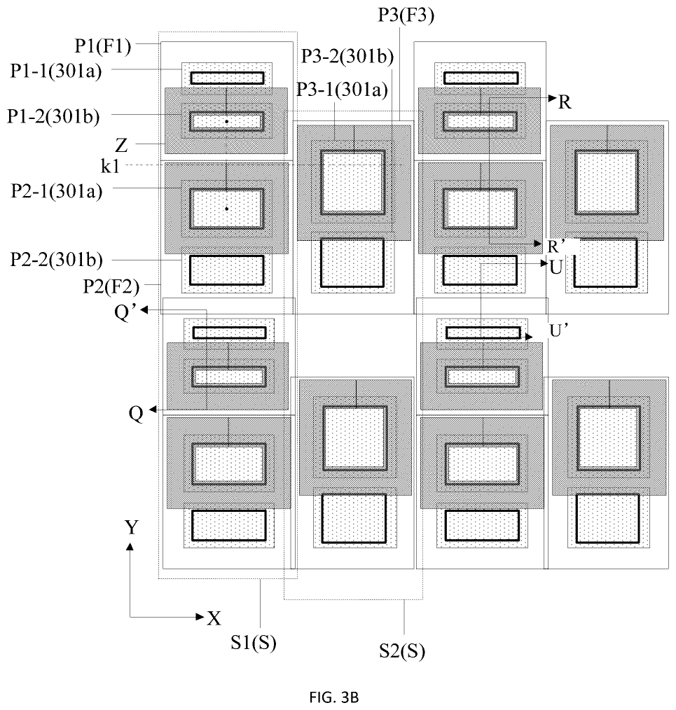

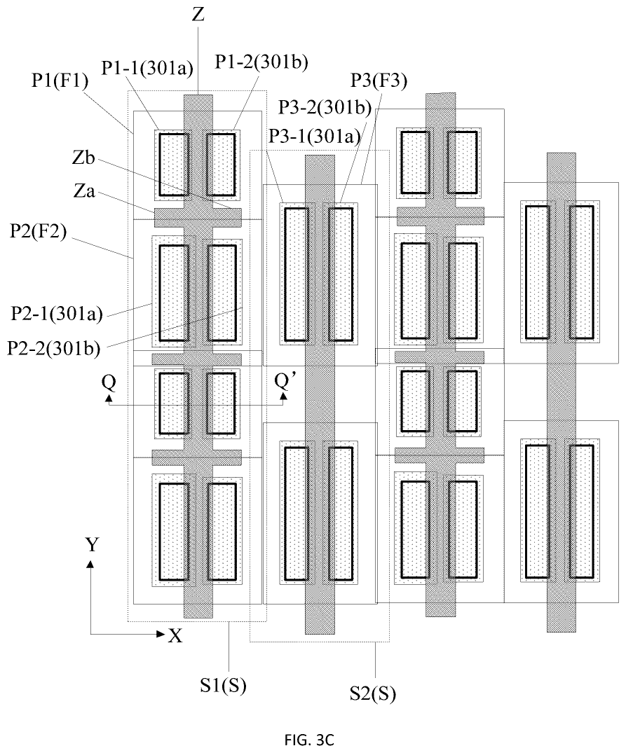

FIG. 3A is a planar schematic diagram of the sub-pixels of the display panel according to at least one embodiment of the present disclosure, specifically, a schematic diagram of the sub-pixel arrangement for realizing a two-way display mode. In some examples, as shown in FIG. 3A, the plurality of sub-pixels in the display region of the display panel may be arranged in an array, for example, sequentially arranged along a first direction X, and sequentially arranged along a second direction Y. Here, the first direction X and the second direction Y may be in the same plane and intersect with each other. For example, the first direction X may be perpendicular to the second direction Y.

FIG. 3B is a planar schematic diagram of the sub-pixels of the display panel according to at least one embodiment of the present disclosure, specifically, a schematic diagram of the sub-pixel arrangement for realizing the anti-peeping display mode. In some examples, as shown in FIG. 3B, the plurality of sub-pixels in the display region of the display panel may be arranged in an array, for example, sequentially arranged along a first direction X, and sequentially arranged along a second direction Y. Here, the first direction X and the second direction Y may be in the same plane and intersect with each other. For example, the first direction X may be perpendicular to the second direction Y.

In some examples, as shown in FIG. 3A and FIG. 3B, the light-emitting element of at least one sub-pixel can be divided into two light-emitting units. For example, as shown in FIG. 3A, the light-emitting element of the first sub-pixel P1 may include: a first light-emitting unit P1-1 and a second light-emitting unit P1-2 arranged along the first direction X; the light-emitting element of the second sub-pixel P2 may include: a first light-emitting unit P2-1 and a second light-emitting unit P2-2 arranged along the first direction X; and the light-emitting element of the third sub-pixel P3 may include: a first light-emitting unit P3-1 and a second light-emitting unit P3-2 arranged along the first direction X. In the first direction X, the first light-emitting unit P1-1 and the second light-emitting unit P1-2 may be arranged at intervals, the first light-emitting unit P2-1 and the second light-emitting unit P2-2 may be arranged at intervals, and the first light-emitting unit P3-1 and the second light-emitting unit P3-2 may be arranged at intervals. For another example, as shown in FIG. 3B, the light-emitting element of the first sub-pixel P1 may include: a first light-emitting unit P1-1 and a second light-emitting unit P1-2 arranged along the second direction Y; the light-emitting element of the second sub-pixel P2 may include: a first light-emitting unit P2-1 and a second light-emitting unit P2-2 arranged along the second direction Y; and the light-emitting element of the third sub-pixel P3 may include: a first light-emitting unit P3-1 and a second light-emitting unit P3-2 arranged along the second direction Y. In the second direction Y, the first light-emitting unit P1-1 and the second light-emitting unit P1-2 may be arranged at intervals, the first light-emitting unit P2-1 and the second light-emitting unit P2-2 may be arranged at intervals, and the first light-emitting unit P3-1 and the second light-emitting unit P3-2 may be arranged at intervals.

In some examples, as shown in FIG. 3A, the first light-emitting unit and the second light-emitting unit of the same light-emitting element are arranged along the first direction X and extend along the second direction Y, and the optical component Z extends along the second direction Y. Specifically, for example, the first light-emitting unit P1-1 and the second light-emitting unit P1-2 of the first sub-pixel P1 are arranged along the first direction X and extend along the second direction Y, the first light-emitting unit P2-1 and the second light-emitting unit P2-2 of the second sub-pixel P2 are arranged along the first direction X and extend along the second direction Y, and the first light-emitting unit P3-1 and the second light-emitting unit P3-2 of the third sub-pixel P1 are arranged along the first direction X and extend along the second direction Y.

In some examples, as shown in FIG. 3A, the display panel includes a plurality of light-emitting element columns S that extend along the second direction Y and are arranged along the first direction X. In the same light-emitting element column S, each first light-emitting unit extends in the same direction, and each second light-emitting unit extends in the same direction. Specifically, for example, the first light-emitting unit P1-1 of the first sub-pixel P1 and the first light-emitting unit P2-1 of the second sub-pixel P2 extend in the same direction and are located in the same column; and the second light-emitting unit P1-2 of the first sub-pixel P1 and the second light-emitting unit P2-2 of the second sub-pixel P2 extend in the same direction and are located in the same column. In the same light-emitting element column S, the optical component between the first light-emitting unit and the second light-emitting unit which are adjacent is an integrally connected structure. In the embodiments of the disclosure, the optical component between the first light-emitting unit and the second light-emitting unit which are adjacent is an integrally connected structure, to facilitate the fabrication of the optical component.

In some examples, as shown in FIG. 3A, the light-emitting element column S includes a first light-emitting element column S1 and a second light-emitting element column S2 that are alternately arranged along the first direction X. The first light-emitting element column S1 includes a first sub-light-emitting element F1 that emits light of a first color and a second sub-light-emitting element F2 that emits light of a second color. The second light-emitting element column S2 includes a third sub-light-emitting element F3 that emits light of a third color. Specifically, the light of a first color can be red light, the light of a second color can be green light, and the light of a third color can be blue light. In other words, the first sub-light-emitting element F1 can be a red (R) sub-light-emitting element, the second sub-light-emitting element F2 can be a green (G) sub-light-emitting element, and the third sub-light-emitting element F3 can be a blue (B) sub-light-emitting element.

In some examples, as shown in FIG. 3A, a light-emitting region of the first light-emitting unit is strip-shaped and extends along the second direction Y, and a light-emitting region of the second light-emitting unit is strip-shaped and extends along the second direction Y. Specifically, for example, a light-emitting region of the first light-emitting unit P1-1 of the first sub-pixel P1 is strip-shaped, a light-emitting region of the first light-emitting unit P2-1 of the second sub-pixel P2 is strip-shaped, and a light-emitting region of the first light-emitting unit P3-1 of the third sub-pixel P1 is strip-shaped. For example, a light-emitting region of the second light-emitting unit P1-2 of the first sub-pixel P1 is strip-shaped, a light-emitting region of the second light-emitting unit P2-2 of the second sub-pixel P2 is strip-shaped, and a light-emitting region of the second light-emitting unit P3-2 of the third sub-pixel P3 is strip-shaped.

In some examples, as shown in FIG. 3A, in the same light-emitting element, an area of a light-emitting region of the first light-emitting unit is approximately equal to an area of a light-emitting region of the second light-emitting unit. Specifically, an area of a light-emitting region of the first light-emitting unit P1-1 of the first sub-pixel P1 is approximately equal to an area of a light-emitting region of the second light-emitting unit P1-2, an area of a light-emitting region of the first light-emitting unit P2-1 of the second sub-pixel P2 is approximately equal to an area of a light-emitting region of the second light-emitting unit P2-2, and an area of a light-emitting region of the first light-emitting unit P3-1 of the third sub-pixel P1 is approximately equal to an area of a light-emitting region of the second light-emitting unit P3-2.

In some examples, for the two-way display mode structure shown in FIG. 3A, the pixel circuit is configured to drive only the first light-emitting unit to emit light in the first display mode and drive only the second light-emitting unit to emit light in the second display mode. Specifically, for example, when only the user in the driver's seat needs to view, the pixel circuit is configured to drive only the first light-emitting unit to emit light. When only the user in the front passenger's seat needs to view, the pixel circuit is configured to drive only the second light-emitting unit to emit light.

In some examples, as shown in FIG. 3B, an orthographic projection of the optical component Z on the substrate surrounds an orthographic projection of the first light-emitting unit on the substrate. Specifically, for example, the orthographic projection of the optical component Z on the substrate only surrounds orthographic projections of the second light-emitting unit P1-2 of the first sub-pixel P1, the first light-emitting unit P2-1 of the second sub-pixel P2, and the first light-emitting unit P3-1 of the third sub-pixel P1 on the substrate.

In some examples, as shown in FIG. 3B, the display panel includes a first light-emitting element column S1 and a second light-emitting element column S2 that extend along the second direction Y and are arranged along the first direction X. The first light-emitting element column S1 includes a first sub-light-emitting element F1 that emits light of a first color and a second sub-light-emitting element F2 that emits light of a second color. The second light-emitting element column S2 includes a third sub-light-emitting element F3 that emits light of a third color. The first light-emitting unit and the second light-emitting unit of the same light-emitting element extend along the first direction X and are arranged along the second direction Y. In the first sub-light-emitting element F1 and the second sub-light-emitting element F2 which are adjacent in the first light-emitting element column S1, the optical component Z surrounds the second light-emitting unit and the first light-emitting unit which are adjacent in different light-emitting elements. Specifically, as shown in FIG. 3B, in the first light-emitting element column S1, the optical component Z surrounds the second light-emitting unit P1-2 of the first sub-light-emitting element F1 and surrounds the first light-emitting unit F1 of the second sub-light-emitting element F2.

In some examples, as shown in FIG. 3B, in the second light-emitting element column S2, the optical component Z surrounds the first light-emitting unit P3-1 of the third sub-light-emitting element F3.

In some examples, as shown in FIG. 3B, in the first light-emitting element column S1, a distance between adjacent optical components Z is smaller than a distance between the first light-emitting unit and the second light-emitting unit of the same light-emitting element. This design aims to make the optical component Z block the light between different sub-pixels and reflect the light of the same light-emitting element.

In some examples, as shown in FIG. 3B, the display panel has a first symmetry line k1. The first symmetry line k1 passes through the first light-emitting unit P3-1 of the third sub-light-emitting element F3. Herein, the first symmetry line k1 passes through a midpoint of a line connecting a first center and a second center. The first center is a center of the second light-emitting unit P1-2 of the first sub-light-emitting element F1, and the second center is a center of the first light-emitting unit P2-1 of the second sub-light-emitting element F2.

In some examples, as shown in FIG. 3C, the light-emitting element of at least one sub-pixel can be divided into two light-emitting units. The light-emitting element of the first sub-pixel P1 can include a first light-emitting unit P1-1 and a second light-emitting unit P1-2 that are arranged along the first direction X; the light-emitting element of the second sub-pixel P2 can include a first light-emitting unit P2-1 and a second light-emitting unit P2-2 that are arranged along the first direction X; and the light-emitting element of the third sub-pixel P3 can include a first light-emitting unit P3-1 and a second light-emitting unit P3-2 that are arranged along the first direction X. In the first direction X, the first light-emitting unit P1-1 and the second light-emitting unit P1-2 can be spaced apart, the first light-emitting unit P2-1 and the second light-emitting unit P2-2 can be spaced apart, and the first light-emitting unit P3-1 and the second light-emitting unit P3-2 can be spaced apart. In the same light-emitting element column S, optical components between at least some of first light-emitting units and second light-emitting units which are adjacent to each other are an integrally connected structure. Between at least some of first light-emitting units P1-1 of the first sub-pixels P1 and first light-emitting units P2-1 of the second sub-pixels P2 which are adjacent to each other, a second optical component Za is also provided; and/or, between at least some of second light-emitting units P1-2 of the first sub-pixels P1 and second light-emitting units P2-2 of the second sub-pixels P2 which are adjacent to each other, a third optical component Zb is also provided. Herein, the second optical component Za and the third optical component Zb prevent light crosstalk between adjacent sub-pixels and simultaneously improve light utilization efficiency. For example, the second optical component Za can prevent light crosstalk between the first light-emitting unit P1-1 of the first sub-pixel P1 and the first light-emitting unit P2-1 of the second sub-pixel P2 adjacent to the first light-emitting unit P1-1 of the first sub-pixel P1, and simultaneously improve light utilization efficiency. Specifically, a structure of the second optical component Za can be the same as that of the optical component Z, that is, the second optical component Za can also include a shielding layer Z1 and a light reflection structure Z2 located on a side of the shielding layer facing the display structure layer.

In some examples, as shown in FIGS. 3A-3C, in at least some sub-pixels, an overlapping area of the optical component Z and the first light-emitting unit is larger than an overlapping area of the optical component Z and the second light-emitting unit. For example, in an anti-peeping display mode structure shown in FIG. 3A, the overlapping area of the optical component Z and the first light-emitting unit is larger than the overlapping area of the optical component Z and the second light-emitting unit. The pixel circuit is configured to drive only the first light-emitting unit to emit light in the first display mode, and drive the second light-emitting unit to emit light together with the first light-emitting unit in the third display mode. Specifically, for example, in the anti-peeping mode, only the first light-emitting unit is driven to emit light; and in the sharing mode, the second light-emitting unit is driven to emit light together with the first light-emitting unit. In some examples, for the anti-peeping display mode structure shown in FIG. 3A, the pixel circuit is configured to drive only the first light-emitting unit to emit light in the first display mode, and drive the second light-emitting unit to emit light together with the first light-emitting unit in the third display mode. Specifically, for example, in the anti-peeping mode, only the first light-emitting unit is driven to emit light; and in the sharing mode, the second light-emitting unit is driven to emit light together with the first light-emitting unit.

In some examples, as shown in FIG. 3C, the second optical component Za and the third optical component Zb can be connected to the optical component Z, for example, as an integral structure. Optionally, a size of the second optical component Za and a size of the third optical component Zb (for example, a width of the second optical component Za and a width of the third optical component Zb in the second direction Y) is smaller than a size of the optical component Z (for example, a width of the optical component Z in the first direction X).

In some examples, as shown in FIG. 3C, FIG. 3C shows an anti-peeping display mode structure. For example, in the anti-peeping mode, only the first light-emitting unit is driven to emit light; and in the sharing mode, the second light-emitting unit is driven to emit light together with the first light-emitting unit. In the first direction X, a length of the second optical component Za is smaller than a length of the third optical component Zb. This design is beneficial for blocking light of the second light-emitting unit in the anti-peeping mode.

In some examples, sizes of the optical components Z corresponding to different sub-pixels can be equal or not completely equal (for example, area, width, or length). For example, as shown in FIGS. 3A and 3C, a width of the optical component Z in the first light-emitting element column S1 is smaller than a width of the optical component Z in the second light-emitting element column S2. For example, as shown in FIG. 3B, an area of the optical component Z corresponding to the first sub-pixel P1-2 is smaller than an area of the optical component Z corresponding to the second sub-pixel P2-1, and is smaller than an area of the optical component Z corresponding to the third sub-pixel P3-1.

In some examples, a light-emitting region of at least one light-emitting element can include a light-emitting region of the first light-emitting unit and a light-emitting region of the second light-emitting unit of the light-emitting element. In at least one light-emitting element, the light-emitting region of the first light-emitting unit and the light-emitting region of the second light-emitting unit can be isolated from each other. In at least one light-emitting element, an area of the light-emitting region of the first light-emitting unit can be approximately the same as an area of the light-emitting region of the second light-emitting unit. In at least one light-emitting element, a shape of the first light-emitting unit can be approximately the same as a shape of the second light-emitting unit. However, this embodiment is not limited to this. For example, shapes of two light-emitting units of at least one light-emitting element can be different. For another example, areas of the light-emitting regions of two light-emitting units of at least one light-emitting element can be different. For example, an area of the light-emitting region of the first light-emitting unit can be larger than an area of the light-emitting region of the second light-emitting unit.

In some embodiments, as shown in FIG. 3A or FIG. 3B, an orthographic projection of the optical component Z on the substrate 101 also covers an orthographic projection of a side region of the first light-emitting unit facing the second light-emitting unit on the substrate 101, and also covers an orthographic projection of a side region of the second light-emitting unit facing the first light-emitting unit on the substrate. Specifically, for example, in the first sub-pixel P1, the orthographic projection of the optical component Z on the substrate 101 also covers the orthographic projection of the side region of the first light-emitting unit P1-1 facing the second light-emitting unit P1-2 on the substrate 101, and also covers the orthographic projection of the side region of the second light-emitting unit P1-2 facing the first light-emitting unit P1-1 on the substrate. Specifically, the orthographic projection of the optical component Z on the substrate 101 can cover an orthographic projection of a side region of a first pixel opening (shown as a black thick frame in FIG. 3A or FIG. 3B and corresponding to a first anode 301a) on the substrate 101 and an orthographic projection of a side region of a second pixel opening (shown as a black thick frame in FIG. 3A or FIG. 3B and corresponding to a second anode 301b) of the pixel definition layer 304 on the substrate 101.

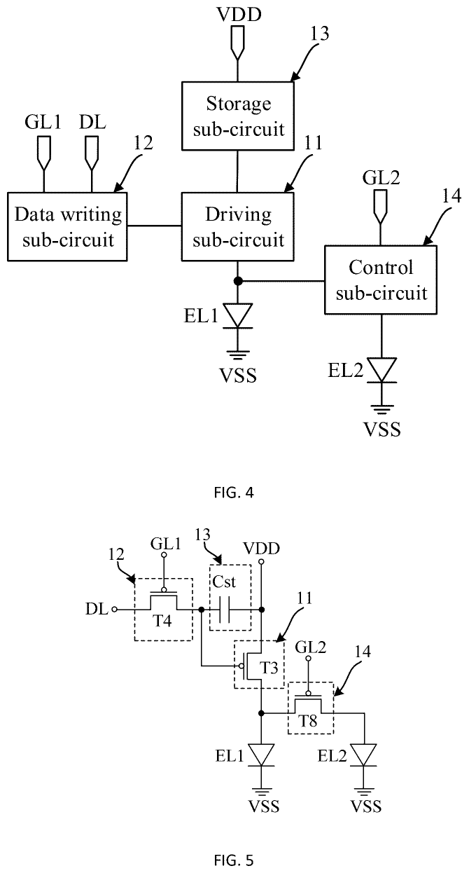

FIG. 4 is a schematic diagram of a pixel circuit according to at least one embodiment of the present disclosure. In some examples, as shown in FIG. 4, the pixel circuit can at least include: a driving sub-circuit 11, a data writing sub-circuit 12, a storage sub-circuit 13, and a control sub-circuit 14. The data writing sub-circuit 12 can be electrically connected to a first scan line GL1, a data line DL and the driving sub-circuit 11, and is configured to provide a data signal transmitted by the data line DL to the driving sub-circuit 11 under the control of the first scan line GL1. The driving sub-circuit 11 can be electrically connected to the storage sub-circuit 13, the data writing sub-circuit 12, the control sub-circuit 14 and a first light-emitting unit EL1, and is configured to drive the first light-emitting unit EL1 to emit light. The storage sub-circuit 13 can be electrically connected to the driving sub-circuit 11 and a first power supply line VDD. The control sub-circuit 14 can be electrically connected to a second scan line GL2, the driving sub-circuit 11, the first light-emitting unit EL1 and a second light-emitting unit EL2, and is configured to control the second light-emitting unit EL2 to emit light together with the first light-emitting unit EL1 under the control of the second scan line GL2.

In some examples, the first light-emitting unit EL1 may include a first anode, a first organic light-emitting layer and a first cathode which are stacked. The second light-emitting unit EL2 may include a second anode, a second organic light-emitting layer and a second cathode which are stacked. The first anode of the first light-emitting unit EL1 may be electrically connected to the driving sub-circuit 11 and the control sub-circuit 14, and the first cathode may be electrically connected to a second power supply line VSS. The second anode of the second light-emitting unit EL2 may be electrically connected to the control sub-circuit 14, and the second cathode may be electrically connected to the second power supply line VSS.

In some examples, the first power supply line VDD may be configured to continuously provide a high-potential first voltage signal, and the second power supply line VSS may be configured to continuously provide a low-potential second voltage signal. The first voltage signal is greater than the second voltage signal.

In some examples, the gate driving circuit in the peripheral region of the display panel may include: a first scan driver and a second scan driver. The first scan driver may be configured to provide a first scan signal to the first scan line, and the second scan driver may be configured to provide a second scan signal to the second scan line.

In some examples, a plurality of transistors of the pixel circuit may adopt low temperature poly-silicon (LTPS) thin-film transistors, or may adopt oxide thin-film transistors, or may adopt both LTPS thin-film transistors and oxide thin-film transistors. An active layer of the LTPS thin-film transistor adopts

TPS, and an active layer of the oxide thin-film transistor adopts oxide. The LTPS thin-film transistor has advantages of high mobility and fast charging, etc., and the oxide thin-film transistor has an advantage of low leakage current, etc. In some examples, the LTPS thin-film transistors and the oxide thin-film transistors can be integrated on a display panel to form a low-temperature polycrystalline oxide display panel, so that the advantages of both can be utilized, the high resolution (PPI, Pixel Per Inch) can be achieved, low-frequency driving can be realized, power consumption can be reduced, and display quality can be improved. However, this embodiment is not limited thereto.

FIG. 5 is an equivalent circuit diagram of a pixel circuit according to at least one embodiment of the present disclosure. In some examples, as shown in FIG. 5, the pixel circuit may have a 3T1C structure. Herein, the driving sub-circuit 11 may include a driving transistor T3, the data writing sub-circuit 12 may include a data writing transistor T4, the storage sub-circuit 13 may include a storage capacitor Cst, and the control sub-circuit 14 may include a first control transistor T8.

In some examples, as shown in FIG. 5, a gate of the data writing transistor T4 is electrically connected to a first scan line GL1, a first electrode of the data writing transistor T4 is electrically connected to a data line DL, and a second electrode of the data writing transistor T4 is electrically connected to a first electrode plate of the storage capacitor Cst1. A second electrode plate of the storage capacitor Cst is electrically connected to the first power supply line VDD. A gate of the driving transistor T3 is electrically connected to a first electrode plate of the storage capacitor Cst, a first electrode of the driving transistor T3 is electrically connected to the first power supply line VDD, and a second electrode of the driving transistor T3 is electrically connected to a first anode of the first light-emitting unit EL1. A gate of the first control transistor T8 is electrically connected to a second scan line GL2, a first electrode of the first control transistor T8 is electrically connected to a first anode of the first light-emitting unit EL1, and a second electrode of the first control transistor T8 is electrically connected to a second anode of the second light-emitting unit EL2.

In some examples, as shown in FIG. 5, taking the driving transistor T3, the data writing transistor T4 and the first control transistor T8 as P-type transistors as an example, when the first scan signal provided by the first scan line GL1 is a low-level signal, the data writing transistor T4 is turned on, the storage capacitor Cst is charged, the data signal transmitted by the data line DL is stored in the storage capacitor Cst, and the data signal stored in the storage capacitor Cst can control a conduction degree of the driving transistor T3 to drive the first light-emitting unit EL1 to emit light. When the second scan signal provided by the second scan line GL2 is a high-level signal, the first control transistor T8 is turned off, and the second light-emitting unit EL2 does not emit light; and when the second scan signal provided by the second scan line GL2 is a low-level signal, the first control transistor T8 is turned on, and the second light-emitting unit EL2 can emit light together with the first light-emitting unit EL1.

In some examples, as shown in FIG. 5, in an anti-peeping display mode, the second scan signal provided by the second scan line GL2 can be continuously a high-level signal, so that the first control transistor T8 is turned off, and the driving transistor T3 can drive only the first light-emitting unit EL1 to emit light under the control of the data signal. In a sharing display mode, the second scan signal provided by the second scan line GL2 can be a low-level signal, the first control transistor T8 is turned on, so that the driving transistor T3 can simultaneously drive the first light-emitting unit EL1 and the second light-emitting unit EL2 to emit light under the control of the data signal.

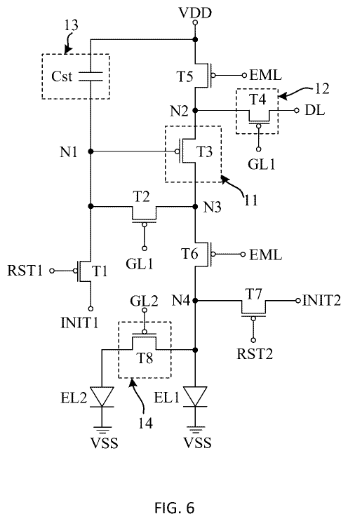

FIG. 6 is another equivalent circuit diagram of a pixel circuit according to at least one embodiment of the present disclosure. In some examples, as shown in FIG. 6, the pixel circuit may have an 8T1C structure. Herein, the driving sub-circuit 11 may include a driving transistor T3, the data writing sub-circuit 12 may include a data writing transistor T4, the storage sub-circuit 13 may include a storage capacitor Cst, and the control sub-circuit 14 may include a first control transistor T8. The pixel circuit may further include: a first reset transistor T1, a second reset transistor T7, a threshold compensation transistor T2, a first light-emitting control transistor T5 and a second light-emitting control transistor T6.

In some examples, as shown in FIG. 6, a gate of the first reset transistor T1 is electrically connected to a first reset control line RST1, a first electrode of the first reset transistor T1 is electrically connected to a first initial signal line INIT1, and a second electrode of the first reset transistor T1 is electrically connected to a first node N1. A gate of the threshold compensation transistor T2 is electrically connected to a first scan line GL1, a first electrode of the threshold compensation transistor T2 is electrically connected to a first node N1, and a second electrode of the threshold compensation transistor T2 is electrically connected to a third node N3. A gate of the driving transistor T3 is electrically connected to a first node N1, a first electrode of the driving transistor T3 is electrically connected to a second node N2, and a second electrode of the driving transistor T3 is electrically connected to the third node N3. A gate of the data writing transistor T4 is electrically connected to the first scan line GL1, a first electrode of the data writing transistor T4 is electrically connected to the data line DL, and a second electrode of the data writing transistor T4 is electrically connected to the second node N2. A gate of the first light-emitting control transistor T5 is electrically connected to a light-emitting control line EML, a first electrode of the first light-emitting control transistor T5 is electrically connected to the first power supply line VDD, and a second electrode of the first light-emitting control transistor T5 is electrically connected to the second node N2. A gate of the second light-emitting control transistor T6 is electrically connected to the light-emitting control line EML, a first electrode of the second light-emitting control transistor T6 is electrically connected to the third node N3, and a second electrode of the second light-emitting control transistor T6 is electrically connected to a fourth node N4. A gate of the second reset transistor T7 is electrically connected to a second reset control line RST2, a first electrode of the second reset transistor T7 is electrically connected to a second initial signal line INIT2, and a second electrode of the second reset transistor T7 is electrically connected to the fourth node N4. A gate of the first control transistor T8 is electrically connected to the second scan line GL2, a first electrode of the first control transistor T8 is electrically connected to the fourth node N4, and a second electrode of the first control transistor T8 is electrically connected to a second anode of the second light-emitting unit EL2. A first electrode plate of the storage capacitor Cst is electrically connected to the first node N1, and a second electrode plate of the storage capacitor Cst is electrically connected to the first power supply line VDD. A first anode of the first light-emitting unit EL1 is electrically connected to the fourth node N4, and a first cathode of the first light-emitting unit EL1 is electrically connected to the second power supply line VSS. A second anode of the second light-emitting unit EL2 is electrically connected to the second electrode of the first control transistor T8, and a second cathode of the second light-emitting unit EL2 is electrically connected to the second power supply line VSS.

In some examples, the first node N1 is a connection point of the first reset transistor T1, the threshold compensation transistor T2, the driving transistor T3 and the storage capacitor Cst. The second node N2 is a connection point of the driving transistor T3, the data writing transistor T4 and the first light-emitting control transistor T5. The third node N3 is a connection point of the driving transistor T3, the threshold compensation transistor T2 and the second light-emitting control transistor T6. The fourth node N4 is a connection point of the second light-emitting control transistor T6, the second reset transistor T7, the first control transistor T8 and the first anode of the first light-emitting unit EL1.

In some examples, all eight transistors of the pixel circuit being P-type transistors are taken as an example for description. Herein, the second reset control line RST2 may be connected to the first scan line GL1 to be input with the first scan signal. In the anti-peeping display mode, the second scan line GL2 may continuously provide a high-level second scan signal, so that the first control transistor T8 is turned off, and the second light-emitting unit EL2 is in a non-light-emitting state. In the sharing display mode, the second scan line GL2 may continuously provide a low-level second scan signal, so that the first control transistor T8 is turned on, and the second light-emitting unit EL2 can emit light together with the first light-emitting unit EL1.

In some examples, taking the first control transistor T8 being turned off in the anti-peeping display mode as an example, a working process of the pixel circuit may include the following.

At a first stage, called a reset stage, the first reset control signal provided by the first reset control line RST1 is a low-level signal to enable the first reset transistor T1 to be turned on, and the first initial signal provided by the first initial signal line INIT1 can be provided to the first node N1 to initialize the first node N1 and clear the original data voltage in the storage capacitor Cst. The first scan signal provided by the first scan line GL1 is a high-level signal, and the light-emitting control signal provided by the light-emitting control line EML is a high-level signal, so that the data writing transistor T4, the threshold compensation transistor T2, the first light-emitting control transistor T5, the second light-emitting control transistor T6 and the second reset transistor T7 are turned off. In this stage, the first light-emitting unit EL1 does not emit light.

At a second stage, called a data writing stage or a threshold compensation stage, the first scan signal provided by the first scan line GL1 is a low-level signal, the first reset control signal provided by the first reset control line RST1 and the light-emitting control signal provided by the light-emitting control line EML are both high-level signals, and the data line DL outputs a data signal. In this stage, since the first electrode plate of the storage capacitor Cst is at a low level, the driving transistor T3 is turned on. The first scan signal is a low-level signal, so that the threshold compensation transistor T2, the data writing transistor T4 and the second reset transistor T7 are turned on. The threshold compensation transistor T2 and the data writing transistor T4 are turned on, so that a data voltage output by the data line DL is provided to the first node N1 through the second node N2, the turned-on driving transistor T3, the third node N3 and the turned-on threshold compensation transistor T2; and a difference between the data voltage output by the data line DL and the threshold voltage of the driving transistor T3 is charged into the storage capacitor Cst. The voltage of the first electrode plate (i.e., the first node N1) of the storage capacitor Cst is Vdata−|Vth|, where Vdata is the data voltage output by the data line DL, and Vth is the threshold voltage of the driving transistor T3. The second reset transistor T7 is turned on, so that the second initial signal provided by the second initial signal line INIT2 is provided to the fourth node N4 to initialize the fourth node N4, to ensure that the first light-emitting unit EL1 does not emit light. The first reset control signal provided by the first reset control line RST1 is a high-level signal, so that the first reset transistor T1 is turned off. The light-emitting control signal provided by the light-emitting control line EML is a high-level signal, so that the first light-emitting control transistor T5 and the second light-emitting control transistor T6 are turned off.

At a third stage, called a light-emitting stage, the light-emitting control signal provided by the light-emitting control line EML is a low-level signal, and the first scan signal provided by the first scan line GL1 and the first reset control signal provided by the first reset control line RST1 are both high-level signals. The light-emitting control signal provided by the light-emitting control line EML is a low-level signal, so that the first light-emitting control transistor T5 and the second light-emitting control transistor T6 are turned on. The first voltage signal output by the first power supply line VDD provides a driving voltage to a first anode of the first light-emitting unit EL1 through the turned-on first light-emitting control transistor T5, the driving transistor T3 and the second light-emitting control transistor T6, to drive the first light-emitting unit EL1 to emit light.

In a driving process of the pixel circuit, the driving current flowing through the driving transistor T3 is determined by a voltage difference between a gate and a first electrode of the driving transistor T3. Since the voltage of the first node N1 is Vdata−|Vth|, the driving current of the driving transistor T3 is:

$$I = K \times {( Vgs - Vth )}^{2} = K \times {[ ( Vdd - Vdata + \vert Vth \vert ) - Vth ]}^{2} = K \times {[ ( Vdd - Vdata ) ]}^{2} .$$

Herein, I is the driving current flowing through the driving transistor T3, that is, the driving current that drives the light-emitting element EL, K is a constant, Vgs is a voltage difference between the gate and the first electrode of the driving transistor T3, Vth is a threshold voltage of the driving transistor T3, Vdata is a data voltage output by the data line DL, and Vdd is a first voltage signal output by the first power supply line VDD.

It can be seen from the above formula that the driving current is independent of the threshold voltage of the driving transistor T3. Therefore, the pixel circuit of the embodiments can better compensate for the threshold voltage of the driving transistor T3.

The above pixel circuit is just an example. The embodiments do not limit the structure of the pixel circuit.

In the example, in the anti-peeping display mode, the first light-emitting unit EL1 of the light-emitting element of the sub-pixel is illuminated, and the second light-emitting unit EL2 is not illuminated, which can limit the light-emitting area and the light-emitting angle of the sub-pixel. In the sharing display mode, the first light-emitting unit EL1 and the second light-emitting unit EL2 of the light-emitting element of the sub-pixel can be illuminated simultaneously, which can increase the light-emitting area and the light-emitting angle of the sub-pixel. This example can achieve the anti-peeping effect and the sharing effect by switching.

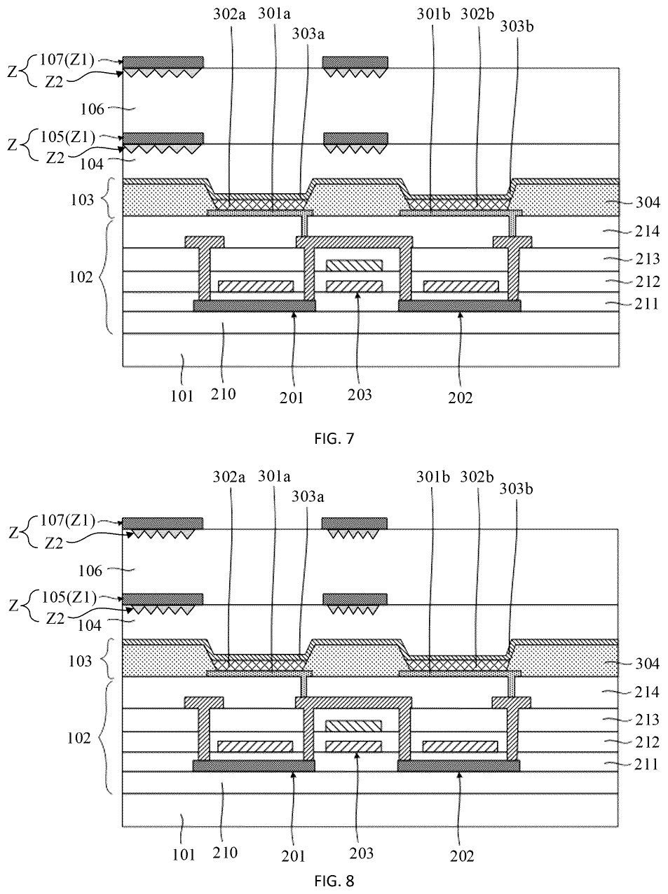

FIG. 7 is a partial cross-sectional diagram along the Q-Q′ direction in FIG. 3A or FIG. 3B or FIG. 3C. FIG. 7 shows a local cross-sectional structure of a first sub-pixel P1. In some examples, as shown in FIG. 7, in a direction perpendicular to the display panel, the display panel may include: a substrate 101; and a display structure layer, an encapsulation structure layer 104, a first shielding layer 105, a first protective layer 106 and a second shielding layer 107 which are sequentially arranged on the substrate 101. The display structure layer may include: a circuit structure layer 102 and a light-emitting structure layer 103, which are sequentially arranged on the substrate 101. In some possible implementation manners, the display panel may include other film layers, such as a spacer column, etc., which is limited in the present disclosure.

In some embodiments, referring to FIG. 7, an orthographic projection of the shielding layer Z1 on the substrate 101 coincides with an orthographic projection of the light reflection structure Z2 on the substrate.

In some embodiments, referring to FIG. 8, an orthographic projection of the shielding layer Z1 on the substrate 101 covers an orthographic projection of the light reflection structure Z2 on the substrate 101, and an area of the orthographic projection of the shielding layer Z1 on the substrate 101 is larger than an area of the orthographic projection of the light reflection structure Z2 on the substrate 101.

In some embodiments, referring to FIG. 7 or FIG. 8, the display panel further includes an encapsulation structure layer 104 located on a light-emitting side of the display structure layer, and a first protective layer 106 located on a side of the encapsulation structure layer 104 facing away from the display structure layer. An optical component Z is disposed between the encapsulation structure layer 104 and the first protective layer 106, and/or an optical component Z is disposed on a side of the first protective layer 106 facing away from the encapsulation structure layer 104.

In some embodiments, referring to FIG. 7 or FIG. 8, the light reflection structure Z2 includes a pit and a reflective filler filled in the pit. The pits are located in the encapsulation structure layer 104 and/or the first protective layer 106.

In some embodiments, a cross-sectional shape of the pits in a direction perpendicular to the substrate 101 is triangular, semicircular, or semi-elliptical.

In some embodiments, referring to FIGS. 4-8, the optical component Z includes a light reflection structure Z2 and a shielding layer Z1. The light reflection structure Z2 includes pits and reflective fillers filled in the pits. The pits are located in the encapsulation structure layer 104 and/or the first protective layer 106. The projection of the optical component Z (for example, the reflection structure Z2) on the substrate 101 overlaps with the projection of the storage capacitor 203 on the substrate 101, and the storage capacitor 203 can be the storage capacitor Cst in the aforementioned pixel circuit. Such a design is conducive to forming at a position corresponding to the storage capacitor, making full use of the layout space, and improving the aperture ratio. For example, the shielding layer Z1 is formed at a position corresponding to the storage capacitor, without occupying the pixel space, which is conducive to reducing the reflective effect of the metal layer of the storage capacitor.

In some embodiments, referring to FIGS. 4-9, the optical component Z includes a light reflection structure Z2 and a shielding layer Z1. The light reflection structure Z2 includes pits. For at least some sub-pixel units, a depth d1 of the pits in the encapsulation structure layer 104 is greater than a depth d2 of the pits in the first protective layer 106. Such a design is conducive to fully reflecting the light emitted by the EL, especially the light of the EL close to the pixel definition layer 304. Of course, for at least some sub-pixel units, a depth of reflective fillers in the pits of the encapsulation structure layer 104 is greater than a depth of reflective fillers in the pits of the first protective layer 106.

In some embodiments, referring to FIGS. 4-9, the optical component Z includes a light reflection structure Z2 and a shielding layer Z1. The light reflection structure Z2 includes pits; and the encapsulation structure layer 104 may include a first encapsulation layer, a second encapsulation layer and a third encapsulation layer which are stacked. The pits in the encapsulation structure layer 104 can be formed in one or more of the first encapsulation layer, the second encapsulation layer or the third encapsulation layer.

In some embodiments, referring to FIGS. 4-9, the optical component Z includes a light reflection structure Z2 and a shielding layer Z1. The light reflection structure Z2 includes pits and reflective fillers filled in the pits. The reflective filler may be a particle with the reflective function, such as titanium dioxide. Of course, the reflective filler may be a metal with the reflective function, such as silver, aluminum. Of course, the reflective filler may also be other organic or inorganic materials with the reflective function. In some embodiments, referring to FIGS. 4-9, the optical component Z includes a light reflection structure Z2 and a shielding layer Z1. The light reflection structure Z2 includes pits. For at least some sub-pixel units, the reflectivity of the reflective filler in the pit of the encapsulation structure layer 104 is higher than that of the reflective filler in the pit of the first protective layer 106. For example, the reflectivity of the reflective filler in the pit of the encapsulation structure layer 104 is 1.5% to 10% higher than that of the reflective filler in the pit of the first protective layer 106. Of course, the reflective fillers in the pits of the encapsulation structure layer 104 and the reflective fillers in the pits of the first protective layer 106 may also be made of the same material.

The following is an exemplary description of a preparation process of the display panel with reference to FIG. 7. The “patterning process” mentioned in the present disclosure, for metal materials, inorganic materials or transparent conductive materials, includes processes such as coating photoresist, mask exposure, development, etching, and stripping of photoresist. The “patterning process” mentioned in the present disclosure, for organic materials, includes processes such as coating organic materials, mask exposure and development. Deposition can adopt any one or more of sputtering, evaporation, or chemical vapor deposition. Coating can adopt any one or more of spraying, spin coating, or inkjet printing. Etching can adopt any one or more of dry etching or wet etching. The present disclosure is not limited herein. A “thin film” refers to a layer of thin film made of a certain material on a substrate by deposition, coating, or other processes. If the “thin film” does not require a patterning process during the entire production process, the “thin film” can also be called a “layer”. If the “thin film” requires a patterning process during the entire production process, it is called a “thin film” before the patterning process and a “layer” after the patterning process. The “layer” after the patterning process contains at least one “pattern”. In the exemplary embodiments of the present disclosure, “an orthographic projection of B is within a range of an orthographic projection of A” or “an orthographic projection of A contains an orthographic projection of B” means that a boundary of the orthographic projection of B is within a boundary range of the orthographic projection of A, or a boundary of the orthographic projection of A overlaps with a boundary of the orthographic projection of B.

In some examples, the preparation process of the display panel may include the following operations.
(1) A substrate 101 is provided. In some examples, the substrate 101 can be a flexible substrate or a rigid substrate. For example, the rigid substrate can include a glass substrate. The flexible substrate can include a first flexible material layer, a first inorganic material layer, a semiconductor layer, a second flexible material layer and a second inorganic material layer which are stacked. The materials of the first flexible material layer and the second flexible material layer can be polyimide (PI), polyethylene terephthalate (PET), or surface-treated polymer soft films, etc. The materials of the first inorganic material layer and the second inorganic material layer can be silicon nitride (SiNx) or silicon oxide (SiOx), etc., which are used to improve the water and oxygen resistance of the substrate. The material of the semiconductor layer can be amorphous silicon (a-Si). However, this embodiment is not limited thereto.
(2) A circuit structure layer 102 is formed. In some examples, the circuit structure layer 102 may include transistors and storage capacitors of a plurality of pixel circuits. FIG. 7 shows a structure of two transistors (for example, a first transistor 201 and a second transistor 202) and one storage capacitor 203 of one pixel circuit for illustration. For example, the first transistor 201 can be the driving transistor T3, the second reset transistor T7 or the second light-emitting control transistor T6 in the aforementioned pixel circuit. The second transistor 202 can be the first control transistor T8 in the aforementioned pixel circuit. The storage capacitor 203 can be the storage capacitor Cst in the aforementioned pixel circuit.

In some examples, as shown in FIG. 7, the circuit structure layer 102 may include: a buffer layer 210, a semiconductor layer, a first insulating layer 211, a first gate metal layer, a second insulating layer 212, a second gate metal layer, a third insulating layer 213, a first source-drain metal layer, and a fourth insulating layer 214, which are sequentially arranged on the substrate 101.

In some examples, as shown in FIG. 7, on the substrate 101 on which the aforementioned structure is formed, a buffer thin film and a semiconductor thin film are sequentially deposited, and the semiconductor thin film is patterned by a patterning process to form the buffer layer 210 and the semiconductor layer disposed on the buffer layer 210. For example, the semiconductor layer may at least include: an active layer of the first transistor 201 and an active layer of the second transistor 202.

Subsequently, on the substrate 101 on which the aforementioned structure is formed, a first insulating thin film and a first conductive thin film are sequentially deposited, and the first conductive thin film is patterned by a patterning process to form the first insulating layer 211 and the first gate metal layer disposed on the first insulating layer 211. For example, the first gate metal layer may at least include: a gate of the first transistor 201, a gate of the second transistor 202, and a first electrode plate of the storage capacitor 203.

In some examples, after the formation of the first gate metal layer, the semiconductor layer can be conductivized by using the first gate metal layer as a shield. The semiconductor layer in the region shielded by the first gate metal layer can form a channel region of the transistor, and the semiconductor layer in the region not shielded by the first gate metal layer can be conductivized, that is, a first region and a second region of the active layer of the plurality of transistors of the pixel circuit are both conductivized.

Subsequently, on the substrate on which the aforementioned structure is formed, a second insulating thin film and a second conductive thin film are sequentially deposited, and the second conductive thin film is patterned by a patterning process to form the second insulating layer 212 and the second gate metal layer disposed on the second insulating layer 212. For example, the second gate metal layer may at least include: a second electrode plate of the storage capacitor 203. An orthographic projection of the second electrode plate of the storage capacitor 203 on the substrate may at least partially overlap with an orthographic projection of the first electrode plate on the substrate.

Subsequently, on the substrate on which the aforementioned structure is formed, a third insulating thin film is deposited, and the third insulating thin film is patterned by a patterning process to form the third insulating layer 213. The third insulating layer 213 may be provided with a plurality of via holes. For example, the plurality of via holes of the third insulating layer 213 can respectively expose surfaces of the semiconductor layer, the first gate metal layer, and the second gate metal layer.

Subsequently, on the substrate on which the aforementioned structure is formed, a third conductive film is deposited, and the third conductive film is patterned by a patterning process to form a first source-drain metal layer on the third insulating layer 213. For example, the first source-drain metal layer may at least include: a first electrode and a second electrode of the first transistor 201, and a first electrode and a second electrode of the second transistor 202. For example, the second electrode of the first transistor 201 and the first electrode of the second transistor 202 may be an integrated structure. Subsequently, a fourth insulating film is coated on the substrate on which the aforementioned structure is formed, and a fourth insulating layer 214 is formed by a patterning process.

In some examples, as shown in combination with FIGS. 5 and 7, the first transistor 201 in FIG. 7 is the third transistor T3 in FIG. 5, and the second transistor 202 in FIG. 7 may be the eighth transistor T8. A first electrode of the first transistor 201 is connected to VDD, and a second electrode of the first transistor 201 is connected to an anode of EL1; and the first electrode of the second transistor 202 is connected to the second electrode of the first transistor 201, and the second electrode of the second transistor 202 is connected to an anode of EL2. In some examples, as shown in combination with FIGS. 6 and 7, the first transistor 201 in FIG. 7 is the sixth transistor T6 in FIG. 6, and the second transistor 202 in FIG. 7 may be the eighth transistor T8 in FIG. 6. The first electrode of the first transistor 201 is connected to the third node N3, and the second electrode of the first transistor 201 is connected to the anode of EL1; and the first electrode of the second transistor 202 is connected to the second electrode of the first transistor 201, and the second electrode of the second transistor 202 is connected to the anode of EL2.

In some examples, the buffer layer 210, the first insulating layer 211, the second insulating layer 212, and the third insulating layer 213 may be inorganic insulating layers; and the fourth insulating layer 214 may be an organic insulating layer. For example, the buffer layer 210, the first insulating layer 211, the second insulating layer 212 and the third insulating layer 213 may be made of any one or more of silicon oxide (SiOx), silicon nitride (SiNx) or silicon oxynitride (SiON), and may be a single layer, multiple layers or a composite layer. Herein, the first insulating layer 211 and the second insulating layer 212 may be referred to as gate insulating (GI) layers, the third insulating layer 213 may be referred to as an interlayer insulating (ILD) layer, and the fourth insulating layer 214 may be referred to as a planarization layer. The first gate metal layer, the second gate metal layer and the first source-drain metal layer may be made of metal materials, such as any one or more of silver (Ag), copper (Cu), aluminum (Al), titanium (Ti) and molybdenum (Mo), or may be made of alloy materials of the above metals, like aluminum-neodymium alloy (AlNd) or molybdenum-niobium alloy (MoNb); and they can be of a single-layer structure, or a multi-layer composite structure, such as Ti/Al/Ti and so on. The semiconductor layer can be made of materials such as amorphous indium gallium zinc oxide (a-IGZO) material, zinc oxynitride (ZnON), indium zinc tin oxide (IZTO), amorphous silicon (a-Si), polycrystalline silicon (p-Si), sexithiophene or polythiophene. That is, the disclosure is applicable to transistors manufactured based on the oxide technology, the silicon technology or the organic material technology.
(3) A light-emitting structure layer 103 is formed. In some examples, the light-emitting structure layer 103 may include a plurality of light-emitting elements.

In some examples, an anode film is deposited on the substrate on which the aforementioned structure is formed, and the anode film is patterned by a patterning process to form an anode layer. For example, the anode layer may include a first anode 301a of the first light-emitting unit and a second anode 301b of the second light-emitting unit. The first anode 301a and the second anode 301b may be independent of each other. The planes where the first anode 301a and the second anode 301b are located may be flush. The first anode 301a may be electrically connected to the second electrode of the first transistor 201 of the pixel circuit through a via hole in the fourth insulating layer 214, and the second anode 301b may be electrically connected to the second electrode of the second transistor 202 of the pixel circuit through a via hole in the fourth insulating layer 214.

Subsequently, a pixel definition film is coated on the substrate on which the aforementioned structure is formed, and a pixel definition layer 304 is formed by a masking, exposure and development process. The pixel definition layer 304 is formed with a plurality of pixel openings which expose the anode layer. For example, the plurality of pixel openings may include a first pixel opening and a second pixel opening. The first pixel opening may expose at least a part of the first anode 301a, and the second pixel opening may expose at least a part of the second anode 301b.

Subsequently, an organic light-emitting layer is formed in the aforementioned formed pixel openings. For example, a first organic light-emitting layer 302a is formed in the first pixel opening, and the first organic light-emitting layer 302a is connected to the first anode 301a; and a second organic light-emitting layer 302b is formed in the second pixel opening, and the second organic light-emitting layer 302b is connected to the second anode 301b.

Subsequently, a cathode film is deposited, and the cathode film is patterned by a patterning process to form a cathode layer. For example, the cathode layer may include a first cathode 303a of the first light-emitting unit and a second cathode 303b of the second light-emitting unit. The first cathode 303a is connected to the first organic light-emitting layer 302a, and the second cathode 303b is connected to the second organic light-emitting layer 302b. The first cathode 303a and the second cathode 303b may be an integrated structure. The first organic light-emitting layer 302a can emit light of a corresponding color under the action of the voltage applied to the first anode 301a and the first cathode 303a; and the second organic light-emitting layer 302b can emit light of a corresponding color under the action of the voltage applied to the second anode 301b and the second cathode 303b. For example, the first light-emitting unit and the second light-emitting unit of the first sub-pixel P1 may both be configured to emit red light.

In some examples, the pixel definition layer 304 may be made of an organic material such as polyimide, acrylic, polyethylene terephthalate, or acrylate. For example, the pixel definition layer 304 may be black. By setting the black pixel definition layer 304, the reflected light and refracted light in the film layer can be absorbed to improve the light-emitting effect of the light-emitting element. However, the embodiment is not limited thereto.

In some examples, the organic light-emitting layer can include a hole injection layer (HIL), a hole transport layer (HTL), an electron block layer (EBL), an emitting layer (EML), a hole block layer (HBL), an electron transport layer (ETL) and an electron injection layer (EIL) which are stacked. In some examples, the first organic light-emitting layer 302a of the first light-emitting unit and the second organic light-emitting layer 302a of the second light-emitting unit may be isolated from each other. However, this embodiment is not limited thereto. For example, in some examples, the hole injection layers of all sub-pixels may be connected together as a common layer, the electron injection layers of all sub-pixels may be connected together as a common layer, the hole transport layers of all sub-pixels may be connected together as a common layer, the electron transport layers of all sub-pixels may be connected together as a common layer, the hole block layers of all sub-pixels may be connected together as a common layer, the emitting layers of adjacent sub-pixels may have a small overlap or may be isolated, and the electron block layers of adjacent sub-pixels may have a small overlap or may be isolated.

In some examples, the light-emitting region of the light-emitting unit may be an overlapping region of the anode, the organic light-emitting layer and the cathode exposed by the pixel opening of the pixel definition layer. For example, a light-emitting region of the first light-emitting unit may be an overlapping region of a first anode, a first organic light-emitting layer and a first cathode in a first pixel opening of the pixel definition layer. A light-emitting region of the second light-emitting unit may be an overlapping region of a second anode, a second organic light-emitting layer and a second cathode in a second pixel opening of the pixel definition layer.
(4) The encapsulation structure layer 104 is formed. In some examples, the encapsulation structure layer 104 is located on a side of the cathode layer away from the substrate 101. The encapsulation structure layer 104 may include a first encapsulation layer, a second encapsulation layer, and a third encapsulation layer which are stacked. Herein, the first encapsulation layer and the third encapsulation layer may be made of an inorganic material, and the second encapsulation layer may be made of an organic material. The second encapsulation layer may be disposed between the first encapsulation layer and the third encapsulation layer to ensure that external water vapor cannot enter the light-emitting structure layer 103. In other examples, the encapsulation structure layer 104 may adopt a laminated structure of inorganic material/organic material/inorganic material/organic material/inorganic material.
(5) The shielding layer Z1 is formed, for example, the first shielding layer 105 is formed. In some examples, black pigment is coated or a black chromium (Cr) film is deposited on the substrate on which the aforementioned structure is formed, and the black pigment or the black chromium film is patterned by a patterning process to form the first shielding layer 105. As shown in FIG. 7, an orthographic projection of the first shielding layer 105 on the substrate 101 may be located within a range of an orthographic projection of the pixel definition layer 304 on the substrate 101.

The pattern of the formed first shielding layer 105 may be as shown in FIG. 3A, FIG. 3B, or FIG. 3C.
(6) The first protective layer 106 is formed. In some examples, a first protective thin film is coated on the substrate on which the aforementioned structure is formed, and the first protective (OC, Over Coat) layer 106 is formed by a patterning process. In some examples, the first protective layer 106 may be made of materials such as acrylate.
(7) The shielding layer Z1 is formed, for example, a second shielding layer 107 is formed. In some examples, black pigment is coated or a black chromium (Cr) film is deposited on the substrate on which the aforementioned structure is formed, and the black pigment or the black chromium film is patterned by a patterning process to form the second shielding layer 107.

In some examples, an orthographic projection of the second shielding layer 107 on the substrate 101 may be located within a range of an orthographic projection of the pixel definition layer 304 on the substrate 101. The orthographic projection of the second shielding layer 107 on the substrate may surround the orthographic projection of the first light-emitting unit on the substrate, and may have no overlap with orthographic projections of light-emitting regions of the first light-emitting unit and the second light-emitting unit on the substrate. For example, the orthographic projection of the second shielding layer 107 on the substrate may be located within a range of the orthographic projection of the first shielding layer 105 on the substrate. For example, the orthographic projection of the second shielding layer 107 on the substrate may coincide with the orthographic projection of the first shielding layer 105 on the substrate. However, this embodiment is not limited thereto.

In this example, by setting two shielding layers (i.e., the first shielding layer 105 and the second shielding layer 107), the emission angle can be limited, which is conducive to realizing the anti-peeping or two-way effect. This embodiment does not limit the number of shielding layers. In other examples, the number of shielding layers may be greater than or equal to three, and a protective layer may be provided between adjacent shielding layers. In other examples, the shielding layer may surround the light-emitting element.

The structure and preparation process of the display panel in the exemplary embodiments of the present disclosure are only an exemplary description. In some exemplary implementation modes, the corresponding structure may be changed and the patterning process may be increased or decreased according to actual needs. For example, the display structure layer may also include a second source-drain metal layer located on a side of the first source-drain metal layer away from the substrate. The second source-drain metal layer may include an anode connection electrode, and the first anode of the first light-emitting unit and the second anode of the second light-emitting unit may be electrically connected to the pixel circuit through the anode connection electrode respectively. However, this disclosure is not limited thereto.

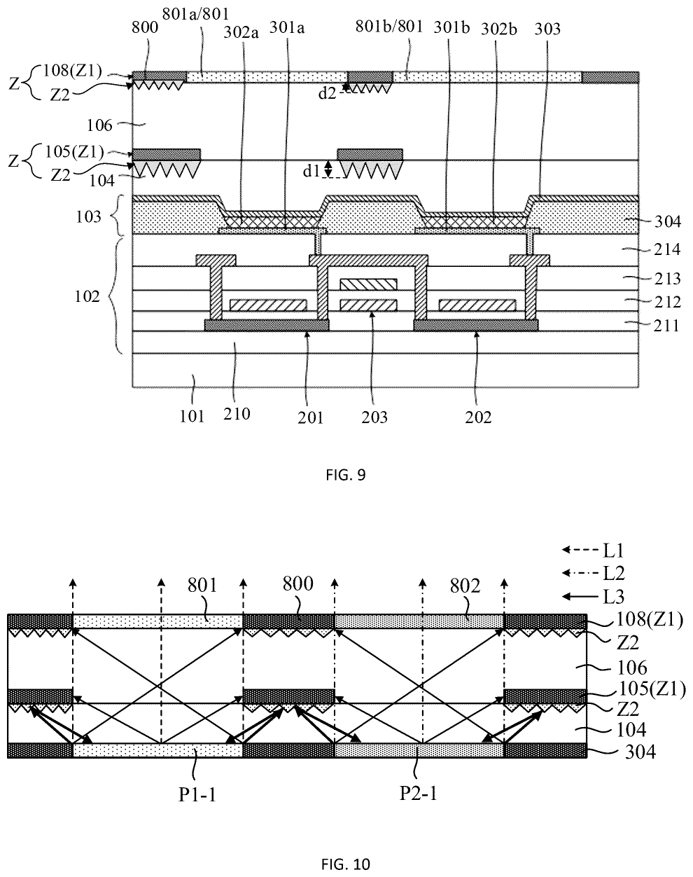

FIG. 9 is another partial cross-sectional diagram in the Q-Q′ direction in FIG. 3A or FIG. 3B or FIG. 3C. In some examples, as shown in FIG. 9, in the direction perpendicular to the display panel, the display panel may include: a substrate 101, and a display structure layer, an encapsulation structure layer 104, a first shielding layer 105, a first protective layer 106 and a color filter layer 108 which are sequentially disposed on the substrate 101. The display structure layer may include a circuit structure layer 102 and a light-emitting structure layer 103 which are sequentially disposed on the substrate 101. For the structures of the display structure layer, the encapsulation structure layer 104, the first shielding layer 105 and the first protective layer 106, reference may be made to the description of the foregoing embodiments, and details are not repeated here.

In some examples, as shown in FIGS. 9 and 10, the color filter layer 108 may be located on a side of the first protective layer 106 away from the substrate 101. The color filter layer 108 may include a plurality of light-filtering units arranged periodically and a black matrix 800 disposed between adjacent light-filtering units. The plurality of light-filtering units may correspond one-to-one to the light-emitting elements of the plurality of sub-pixels. For example, the plurality of light-filtering units may include a first light-filtering unit 801, a second light-filtering unit 802, and a third light-filtering unit. The first light-filtering unit 801 may correspond to the light-emitting element of the first sub-pixel P1, the second light-filtering unit 802 may correspond to the light-emitting element of the second sub-pixel P2, and the third light-filtering unit may correspond to the light-emitting element of the third sub-pixel P3. For example, the first light-filtering unit 801 may be a red light-filtering unit, the second light-filtering unit 802 may be a green light-filtering unit, and the third light-filtering unit may be a blue light-filtering unit.

In this embodiment, the light-filtering unit may allow light of a single color to pass through and absorb light of other colors. For example, the blue light-filtering unit may allow blue light to pass through and absorb light of other colors, the red light-filtering unit may allow red light to pass through and absorb light of other colors, and the green light-filtering unit may allow green light to pass through and absorb light of other colors.

In some examples, at least one light-filtering unit may include a first sub-light-filtering unit and a second sub-light-filtering unit. An orthographic projection of the light-filtering unit on the substrate may cover an orthographic projection of the light-emitting region of the corresponding light-emitting element on the substrate. For example, as shown in FIG. 9, the first light-filtering unit 801 may include a first sub-light-filtering unit 801a and a second sub-light-filtering unit 801b. An orthographic projection of the first sub-light-filtering unit 801a on the substrate 101 may cover the orthographic projection of the light-emitting region of the first light-emitting unit of the first sub-pixel on the substrate 101; and an orthographic projection of the second sub-light-filtering unit 801b on the substrate 101 may cover the orthographic projection of the light-emitting region of the second light-emitting unit of the first sub-pixel on the substrate 101. However, this embodiment is not limited thereto. In other examples, the orthographic projection of a light-filtering unit on the substrate may cover the orthographic projections of the light-emitting regions of the first light-emitting unit and the second light-emitting unit of the corresponding light-emitting element on the substrate.

In some examples, after the first protective layer 106 is fabricated, the color filter layer 108 can be prepared in the following way: black pigment is coated or a black chromium (Cr) film is deposited on the first protective layer 106, and the black pigment or the black chromium film is patterned by a patterning process to form a black matrix 800; and subsequently, a plurality of first light-filtering units 801, a plurality of second light-filtering units, and a plurality of third light-filtering units are formed in sequence. Taking the first light-filtering unit 801 as a red light-filtering unit as an example, red resin is first coated on the first protective layer 106 on which the black matrix 800 has been formed; and after baking and curing, a red light-filtering unit is formed through mask exposure and development. The formation processes of the green light-filtering unit and the blue light-filtering unit are similar, and will not be repeated here.

In this example, by setting a shielding layer (i.e., the first shielding layer) and the color filter layer, the emission angle of the first light-emitting unit is limited, which is conducive to achieving the two-way or anti-peeping effect. By arranging a light reflection structure on a side of the shielding layer facing the substrate, the light incident on a position of the shielding layer can be reflected and then emitted, thereby improving the light output efficiency. This embodiment does not limit the number of shielding layers. In other examples, at least two shielding layers can be arranged between the encapsulation structure layer and the color filter layer, and a protective layer can be arranged between adjacent shielding layers.

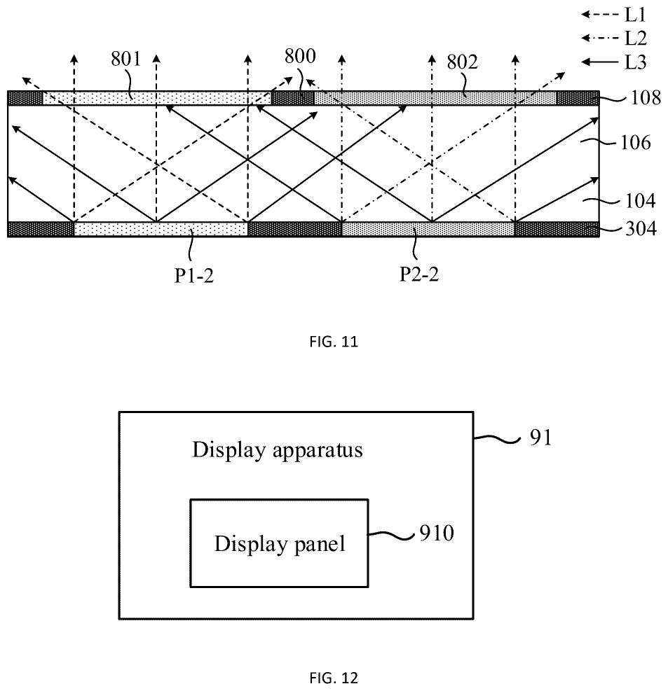

FIG. 10 is a schematic diagram of light emission of a cross-sectional structure along the R-R′ direction in FIG. 3B. FIG. 11 is a schematic diagram of light emission of a cross-sectional structure along the U-U′ direction in FIG. 3B. In FIGS. 10 and 11, some film layers of the substrate and the display structure layer are omitted. FIG. 10 illustrates the emitted light of the first light-emitting unit P1-1 of the first sub-pixel P1 and the first light-emitting unit P2-1 of the second sub-pixel P2 as an example. FIG. 11 illustrates the emitted light of the second light-emitting unit P1-2 of the first sub-pixel P1 and the second light-emitting unit P2-2 of the second sub-pixel P2 as an example. Herein, the emitted light L1 of the first sub-pixel P1 can be represented by a dashed line with an arrow, the emitted light L2 of the second sub-pixel P2 can be represented by a long and short dash line with an arrow, and the light L3 absorbed by film layers in the display panel can be represented by a solid line with an arrow.

In this example, a front viewing angle direction can be a direction perpendicular to a plane where the display panel is located. An oblique viewing angle direction can refer to the line-of-sight direction other than the front viewing angle direction.

In some examples, as shown in FIG. 3B and FIG. 10, an orthographic projection of the first shielding layer 105 on the substrate can surround the orthographic projection of the light-emitting region of the first light-emitting unit P1-1 on the substrate. The emitted light of the first light-emitting unit P1-1 of the first sub-pixel P1 can be emitted along the front viewing angle direction. The emitted light of the first light-emitting unit P1-1 in the right oblique viewing direction will be absorbed by the first shielding layer 105 and the black matrix 800 of the color filter layer 108, and the emitted light of the first light-emitting unit P1-1 in the left oblique viewing direction will be absorbed by the first shielding layer 105 and the black matrix 800 of the color filter layer 108. Similarly, the emitted light of the first light-emitting unit P2-1 of the second sub-pixel P2 can be emitted along the front viewing angle direction, and the emitted light in the oblique viewing direction will be absorbed by the first shielding layer 105 and the black matrix 800 of the color filter layer 108. In this example, when the first light-emitting unit is lit, the emission angle of the emitted light of the first light-emitting unit is limited by the first shielding layer 105 and the black matrix 800 of the color filter layer 108, which can improve the anti-peeping effect of the display panel along the first direction X. The setting of the light reflection structure Z2, as shown by a thick arrow in the figure, can make the light that irradiates on the first shielding layer 105 and the black matrix 800 of the color filter layer 108 be reflected back to the light-emitting element; and then after being reflected by the reflective anode of the light-emitting element, the light is emitted again, thereby improving the light output efficiency of the display panel.

A size of the black matrix 800 between adjacent second light-emitting units can be smaller than a size of the black matrix 800 between adjacent first light-emitting units. The emitted light of the second light-emitting unit P1-2 of the first sub-pixel P1 can be emitted not only along the front viewing angle direction but also along some oblique viewing angle directions. In this example, the emission angle of the emitted light of the second light-emitting unit can be larger than the emission angle of the emitted light of the first light-emitting unit. In the sharing display mode of the display panel, the first light-emitting unit and the second light-emitting unit can be lit simultaneously, and the emission angle of the emitted light of the second light-emitting unit is larger than the emission angle of the emitted light of the first light-emitting unit, which is conducive to achieving the sharing display effect and thus improving the user experience.

In some examples, the black matrix 800 between the first light-emitting units can serve as the first shielding layer 105.

This embodiment also provides a preparation method for a display panel, including: forming a display structure layer on a substrate, the display structure layer including a plurality of sub-pixels. At least one of the plurality of sub-pixels includes: a pixel circuit and a light-emitting element electrically connected to the pixel circuit. The light-emitting element includes: a first light-emitting unit and a second light-emitting unit; and the light-emitting region of the first light-emitting unit and the light-emitting region of the second light-emitting unit are isolated from each other. The pixel circuit is configured to drive at least one of the first light-emitting unit and the second light-emitting unit to emit light in the anti-peeping display mode.

For the preparation method of the display panel in this embodiment, reference can be made to the description of the foregoing embodiments, and thus it will not be repeated here.

FIG. 12 is a schematic diagram of a display apparatus according to at least one embodiment of the present disclosure. In some examples, as shown in FIG. 12, this embodiment provides a display apparatus 91, including the display panel 910 in the foregoing embodiments. In some examples, the display panel 910 can be an OLED display substrate, a QLED display substrate, a Micro-LED display substrate, or a Mini-LED display substrate. The display apparatus 91 can be any product or component with a display function, such as a mobile phone, a tablet computer, a television, a monitor, a laptop computer, a digital photo frame, or a navigator. However, this embodiment is not limited thereto.

Although the preferred embodiments of the present disclosure have been described, those skilled in the art can make additional changes and modifications to these embodiments once the basic creative concepts are known. Therefore, the appended claims are intended to be construed to include the preferred embodiments as well as all changes and modifications falling within the scope of the present disclosure.

Obviously, those skilled in the art can make various changes and variations to the present disclosure without departing from the spirit and scope of the present disclosure. In this way, if these modifications and variations of the present disclosure fall within the scope of the claims of the present disclosure and their equivalent technologies, the present disclosure also intends to include these changes and variations.

1.-20. (canceled)

21. A display panel, comprising:
a substrate;
a display structure layer, disposed on a side of the substrate, and comprising a plurality of sub-pixels; wherein at least one of the plurality of sub-pixels comprises: a pixel circuit and a light-emitting element electrically connected to the pixel circuit; the light-emitting element comprises a first light-emitting unit and a second light-emitting unit; a light-emitting region of the first light-emitting unit and a light-emitting region of the second light-emitting unit are isolated from each other; and the pixel circuit is configured to drive at least one of the first light-emitting unit and the second light-emitting unit to emit light according to a display mode; and
optical components disposed on a light-emitting side of the display structure layer; wherein an orthographic projection of the optical component on the substrate at least partially covers a region between the first light-emitting unit and the second light-emitting unit; and the optical component comprises a shielding layer and a light reflection structure disposed on a side of the shielding layer facing the display structure layer.

22. The display panel according to claim 21, wherein the first light-emitting unit and the second light-emitting unit of one same light-emitting element are arranged along a first direction and extend along a second direction; and the optical component extends along the second direction.

23. The display panel according to claim 22, wherein the display structure layer comprises a plurality of light-emitting element columns extending along the second direction and arranged along the first direction;
in one same light-emitting element column, the first light-emitting units extend in one same direction, the second light-emitting units extend in one same direction, and the optical component between the first light-emitting unit and the second light-emitting unit which are adjacent is an integrally connected structure.

24. The display panel according to claim 23, wherein the plurality of light-emitting element columns comprise first light-emitting element columns and second light-emitting element columns alternately arranged along the first direction;
the first light-emitting element column comprises a first sub-light-emitting element which emits light of a first color and a second sub-light-emitting element which emits light of a second color;
the second light-emitting element column comprises a third sub-light-emitting element which emits light of a third color.

25. The display panel according to claim 22, wherein the light-emitting region of the first light-emitting unit is strip-shaped and extends along the second direction; and the light-emitting region of the second light-emitting unit is strip-shaped and extends along the second direction.

26. The display panel according to claim 25, wherein in the one same light-emitting element, an area of the light-emitting region of the first light-emitting unit is approximately equal to an area of the light-emitting region of the second light-emitting unit.

27. The display panel according to claim 21, wherein the display mode comprises a first display mode and a second display mode;
the pixel circuit is configured to drive only the first light-emitting unit to emit light in the first display mode and drive only the second light-emitting unit to emit light in the second display mode.

28. The display panel according to claim 21, wherein the orthographic projection of the optical component on the substrate surrounds an orthographic projection of the first light-emitting unit on the substrate.

29. The display panel according to claim 28, wherein the display structure layer comprises first light-emitting element columns and second light-emitting element columns extending along a second direction and arranged along a first direction;
the first light-emitting element column comprises: a first sub-light-emitting element which emits light of a first color and a second sub-light-emitting element which emits light of a second color;
the second light-emitting element column comprises: a third sub-light-emitting element which emits light of a third color;
for one same light-emitting element, the first light-emitting unit and the second light-emitting unit extend along the first direction and are arranged along the second direction;
in the first sub-light-emitting element and the second sub-light-emitting element which are adjacent in the first light-emitting element column; and
the optical component surrounds the second light-emitting unit and the first light-emitting unit which are adjacent in different light-emitting elements.

30. The display panel according to claim 29, wherein in the first light-emitting element column, the optical component surrounds the second light-emitting unit of the first sub-light-emitting element and the first light-emitting unit of the second sub-light-emitting element.

31. The display panel according to claim 29, wherein in the second light-emitting element column, the optical component surrounds the first light-emitting unit of the third sub-light-emitting element.

32. The display panel according to claim 29, wherein the display panel has a first symmetry line, and the first symmetry line passes through the first light-emitting unit of the third sub-light-emitting element;
wherein the first symmetry line passes through a midpoint of a line connecting a first center and a second center, the first center is a center of the second light-emitting unit of the first sub-light-emitting element, and the second center is a center of the first light-emitting unit of the second sub-light-emitting element.

33. The display panel according to claim 28, wherein the display mode comprises a first display mode and a third display mode;
the pixel circuit is configured to drive only the first light-emitting unit to emit light in the first display mode and drive the second light-emitting unit to emit light together with the first light-emitting unit in the third display mode.

34. The display panel according to claim 21, wherein the orthographic projection of the optical component on the substrate further covers an orthographic projection of a side region of the first light-emitting unit facing the second light-emitting unit on the substrate, and further covers an orthographic projection of a side region of the second light-emitting unit facing the first light-emitting unit on the substrate.

35. The display panel according to claim 21, wherein an orthographic projection of the shielding layer on the substrate coincides with an orthographic projection of the light reflection structure on the substrate.

36. The display panel according to claim 35, wherein the orthographic projection of the shielding layer on the substrate covers the orthographic projection of the light reflection structure on the substrate, and an area of the orthographic projection of the shielding layer on the substrate is larger than an area of the orthographic projection of the light reflection structure on the substrate.

37. The display panel according to claim 21, further comprising:
an encapsulation structure layer disposed on the light-emitting side of the display structure layer, and
a first protective layer disposed on a side of the encapsulation structure layer facing away from the display structure layer;
wherein the optical components are disposed between the encapsulation structure layer and the first protective layer, and/or the optical components are disposed on a side of the first protective layer facing away from the encapsulation structure layer.

38. The display panel according to claim 37, wherein the light reflection structure comprises a pit and a reflective filler filled in the pit; and the pit is disposed in the encapsulation structure layer and/or the first protective layer.

39. The display panel according to claim 38, wherein a cross-sectional shape of the pit in a direction perpendicular to the substrate is triangular, semi-circular or semi-elliptical.

40. A display apparatus, comprising the display panel according to claim 21.
